(19) United States
(12) Patent Application Publication
(10) Pub. No.: US 2025/0349617 A1
(43) Pub. Date: Nov. 13, 2025

(54) BACKSIDE CONTACT RESISTANCE REDUCTION

(71) Applicant: Taiwan Semiconductor Manufacturing Company, Ltd., Hsin-Chu (TW)

(72) Inventor: Chen-Ming Lee, Taoyuan County (TW)

(21) Appl. No.: 19/275,161

(22) Filed: Jul. 21, 2025

Related U.S. Application Data
(63) Continuation of application No. 18/404,345, filed on Jan. 4, 2024.
(60) Provisional application No. 63/520,255, filed on Aug. 17, 2023.
(60) Provisional application No. 63/611,009, filed on Dec. 15, 2023.

(51) Int. Cl. H01L 21/768; H01L 23/48; H10D 84/01; H10D 84/03; H10D 84/83

(52) U.S. Cl. CPC H01L 21/76898; H01L 23/481; H10D 84/017; H10D 84/038; H10D 84/83

(57) ABSTRACT

In an embodiment, an exemplary method includes forming a source/drain opening extending into a substrate, forming a semiconductor layer in a bottom portion of the source/drain opening, forming a dielectric feature in the source/drain opening and on the semiconductor layer, epitaxially growing a source/drain feature in the source/drain opening, wherein the source/drain feature is in direct contact with the dielectric feature, removing the semiconductor layer and a portion of the substrate disposed directly under the semiconductor layer to form a trench, selectively removing the dielectric feature to enlarge the trench, after the selectively removing of the dielectric feature, forming a silicide layer in the enlarged trench, and depositing a conductive layer in the enlarged trench and in direct contact with the silicide layer.

### PRIORITY DATA

This application is a continuation application of U.S. patent application Ser. No. 18/404,345, filed Jan. 4, 2024, which claims the priority of U.S. Provisional Application Ser. No. 63/520,255, filed Aug. 17, 2023 and the priority of U.S. Provisional Application Ser. No. 63/611,009, filed Dec. 15, 2023, each of which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

As integrated circuit (IC) technologies progress towards smaller technology nodes, parasitic resistance of source/drain contacts may have serious bearings on the overall performance of an IC device. While existing source/drain contacts are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure, according to one or more aspects of the present disclosure.

FIG. 2 illustrates a fragmentary top view of an exemplary workpiece to undergo various stages of operations in the method of FIG. 1, according to various aspects of the present disclosure.

FIGS. 3A, 4A, 5A, 6A, 7A, 8A, 9A, 10A, 11A, 12A, 13A, 14A, 15A, 16A, and 17A (FIGS. 3A-17A) illustrate fragmentary cross-sectional views of the workpiece taken along line A-A′ as shown in FIG. 2 during various fabrication stages in the method of FIG. 1, according to one or more aspects of the present disclosure.

FIGS. 3B, 4B, 5B, 6B, 7B, 8B, 9B, 10B, 11B, 12B, 13B, 14B, 15B, 16B, and 17B (FIGS. 3B-17B) illustrate fragmentary cross-sectional views of the workpiece taken along line B-B′ as shown in FIG. 2 during various fabrication stages in the method of FIG. 1, according to one or more aspects of the present disclosure.

FIGS. 3C, 4C, 8C, 9C, 10C, 11C, 12C, 13C, 14C, 15C, and 16C illustrate fragmentary cross-sectional views of the workpiece taken along line C-C′ as shown in FIG. 2 during various fabrication stages in the method of FIG. 1, according to one or more aspects of the present disclosure.

FIG. 9D illustrates a fragmentary top view of the workpiece shown in FIG. 9C, according to one or more aspects of the present disclosure.

FIG. 18 illustrates a fragmentary cross-sectional view of a first alternative workpiece, according to one or more aspects of the present disclosure.

FIGS. 19A, 19B, 19C, 20A, 20B, and 20C illustrate fragmentary cross-sectional views of a second alternative workpiece, during various fabrication stages in the method of FIG. 1, according to one or more aspects of the present disclosure.

FIGS. 21A, 21B, 21C, 22A, 22B, and 22C illustrate fragmentary cross-sectional views of a third alternative workpiece, during various fabrication stages in the method of FIG. 1, according to one or more aspects of the present disclosure.

FIGS. 23A and 23B illustrate fragmentary cross-sectional views of a fourth alternative workpiece, during various fabrication stages in the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

As integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A gate-all-around (GAA) transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

Silicide layers and source/drain contacts may be formed under epitaxial layers of source/drain features from its back side. In some existing embodiments, to increase landing area of the backside silicide layer and the backside source/drain contact, the epitaxial layers of the source/drain feature may be recessed, which adversely impacts the volume of the source/drain feature and the overall performance.

The present disclosure provides a method for increasing contact area between the backside silicide layer and the source/drain feature without substantially reducing the volume of the source/drain feature from its back side. In an exemplary method, after forming a source/drain opening and refilling a lower portion of the source/drain opening with a semiconductor layer, a dielectric layer is formed to block a top surface of the semiconductor layer such that the source/drain feature that is obtained by performing an epitaxial growth process would not be formed from the bottom up, which leads to formation of voids adjacent to the source/drain feature. After forming the source/drain feature, a first etching process is performed to form a backside opening exposing the dielectric layer, a second etching process is performed to remove the dielectric layer to expose the bottom surface of the source/drain feature. A backside silicide layer is then formed under the source/drain feature and fills the void. Forming the backside silicide layer in the void increases the contact area between the backside silicide layer and the source/drain feature and thus reduce a parasitic resistance of the semiconductor structure.

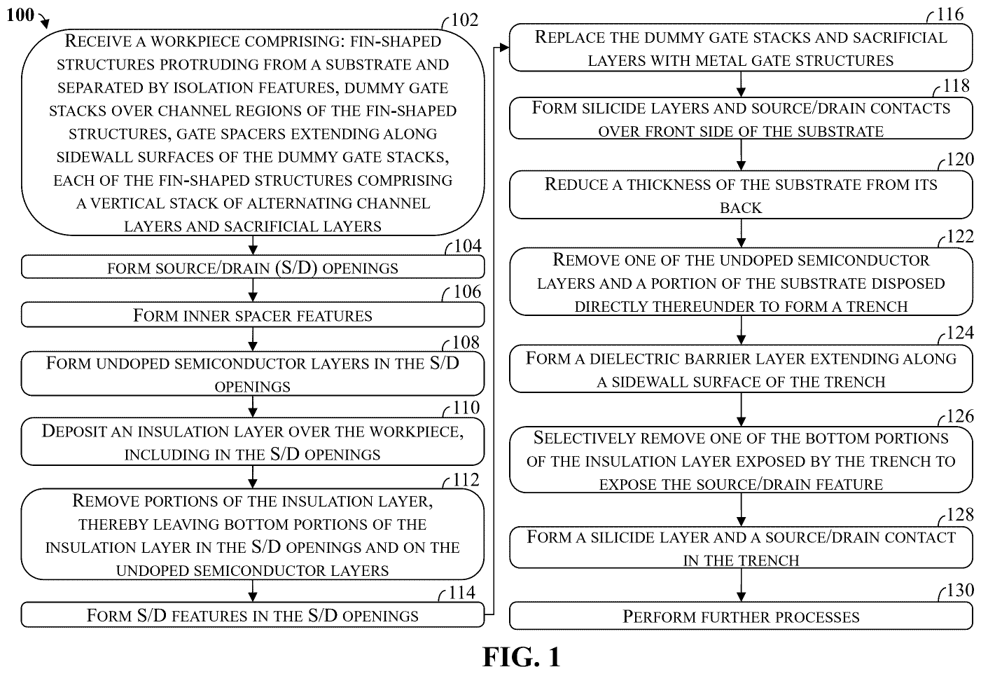

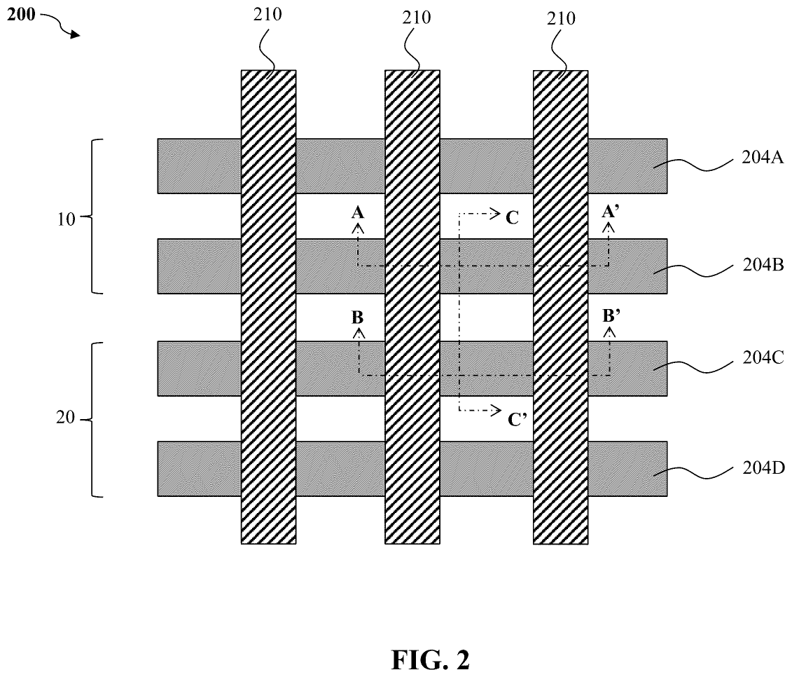

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2 and 3A-23B which are fragmentary top/cross-sectional views of a workpiece 200 at different stages of fabrication according to embodiments of method 100. Method 100 is merely an example and is not intended to limit the present disclosure to what is explicitly illustrated therein. Additional steps may be provided before, during and after the method 100, and some steps described can be replaced, eliminated, or moved around for additional embodiments of the method. Not all steps are described herein in detail for reasons of simplicity. Because the workpiece 200 will be fabricated into a semiconductor structure upon conclusion of the fabrication processes, the workpiece 200 may be referred to as the semiconductor structure 200 as the context requires. For avoidance of doubts, the X, Y and Z directions in FIGs. FIGS. 2 and 3A-23B are perpendicular to one another and are used consistently throughout the present disclosure. Throughout the present disclosure, like reference numerals denote like features unless otherwise excepted.

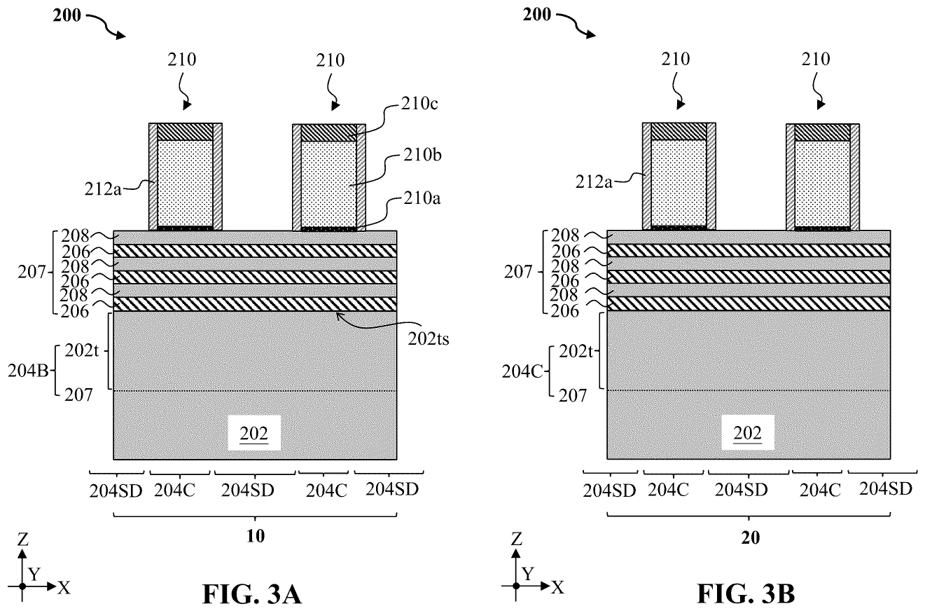

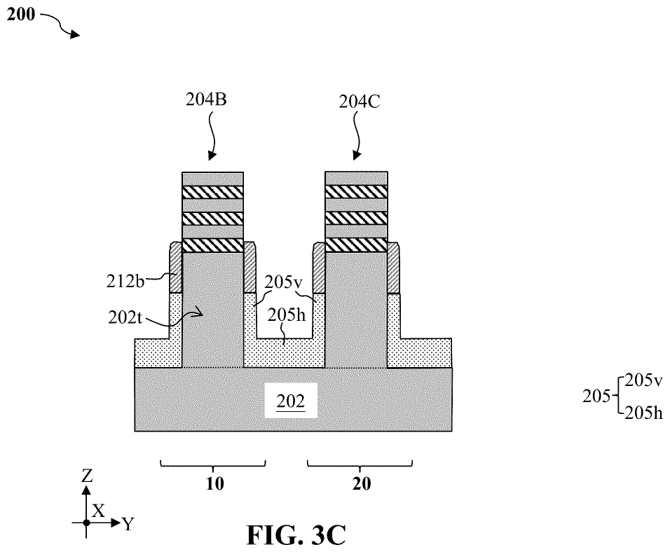

Referring to FIGS. 1, 2, and 3A-3C, method 100 includes a block 102 where a workpiece 200 that includes a first region 10 and a second region 20 is received. FIG. 2 depicts a fragmentary top view of a workpiece 200 to undergo various stages of operations in the method of FIG. 1, according to various aspects of the present disclosure. FIG. 3A illustrates a fragmentary cross-sectional view of the workpiece 200 taken along line A-A′ as shown in FIG. 2, FIG. 3B illustrates a fragmentary cross-sectional view of the workpiece 200 taken along line B-B′ as shown in FIG. 2, and FIG. 3C illustrates a fragmentary cross-sectional view of the workpiece 200 taken along line C-C′ as shown in FIG. 2. As illustrated in FIGS. 3A-3C, the workpiece 200 includes a substrate 202. The substrate 202 may be an elementary (single element) semiconductor, such as silicon (Si) or germanium (Ge) in a crystalline structure; a compound semiconductor, such as silicon carbide (SiC), gallium arsenic (GaAs), gallium phosphide (GaP), indium phosphide (InP), indium arsenide (InAs), and/or indium antimonide (InSb); an alloy semiconductor such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); a non-semiconductor material, such as soda-lime glass, fused silica, fused quartz, and/or calcium fluoride (CaF₂); and/or combinations thereof. In one embodiment, the substrate 202 is a silicon (Si) substrate. The substrate 202 may be uniform in composition or may include various layers, some of which may be selectively etched to form fin-shaped active regions (e.g., the fin-shaped active regions 204A-204D). The layers may have similar or different compositions, and in various embodiments, some substrate layers have non-uniform compositions to induce device strain and thereby tune device performance. Examples of layered substrates include silicon-on-insulator (SOI) substrates 202. In some such examples, a layer of the substrate 202 may include an insulator such as a semiconductor oxide, a semiconductor nitride, a semiconductor oxynitride, a semiconductor carbide, and/or other suitable insulator materials. Doped regions, such as wells, may be formed in the substrate 202. In the embodiments represented in FIG. 2, a portion of the substrate 202 in the first region 10 is doped with an n-type dopant and may be referred to as an n-type well (not shown), and a portion of the substrate 202 in the second region 20 is doped with a p-type dopant and may be referred to as a p-type well (not shown). The n-type dopant may include phosphorus (P) or arsenic (As). The p-type dopant may include boron (B), boron difluoride (BF₂), or indium (In). The n-type well and the p-type well may be formed using ion implantation or thermal diffusion and may be considered portions of the substrate 202. As will be described further below, the first region 10 is p-type field effect transistor (PFET) region for forming PFET(s) and the second region 20 is an n-type field effect transistor (NFET) region for forming NFET(s).

Still referring to FIGS. 2 and 3A-3C, the workpiece 200 includes a number of fin-shaped active regions (e.g., fin-shaped active regions 204A, 204B, 204C, 204D) protruding from the substrate 202. In the present embodiments, the first region 10 includes a fin-shaped active region 204A and a fin-shaped active region 204B extending vertically from the substrate 202, and the second region 20 includes a fin-shaped active region 204C and a fin-shaped active region 204D extending vertically from the substrate 202. The number of fin-shaped active regions depicted in FIGS. 2 and 3A-3C is just an example, the workpiece 200 may include any suitable number of active regions. Each of the fin-shaped active regions 204A-204D may be formed from a top portion 202t (shown in FIGS. 3A-3B) of the substrate 202 and a vertical stack 207 of alternating semiconductor layers disposed on a top surface 202ts of the substrate 202. In an embodiment, the vertical stack 207 includes a number of channel layers 208 interleaved by a number of sacrificial layers 206. Each of the channel layers 208 may include a semiconductor material such as, silicon, germanium, silicon carbide, silicon germanium, GeSn, SiGeSn, SiGeCSn, other suitable semiconductor materials, or combinations thereof, while each sacrificial layer 206 has a composition different from that of the channel layers 208. In an embodiment, each of the channel layers 208 includes silicon (Si), the sacrificial layer 206 includes silicon germanium (SiGe). Although the vertical stack 207 of the depicted example includes three channel layers and three sacrificial layers, it is understood that the vertical stack 207 may include any suitable number (e.g., 2 to 10) of channel layers and any suitable number sacrificial layers. The vertical stack 207 and the top portion 202t of the substrate 202 are then patterned to form the fin-shaped active regions 204A-204D. In some embodiments, the patterned top portion 202t of the substrate 202 may be referred to as a mesa structure 202t. Each of the fin-shaped active regions 204 extends lengthwise along the X direction and is divided into channel regions 204C overlapped by dummy gate stacks 210 (to be described below) and source/drain regions 204SD not overlapped by the dummy gate stacks 210. Source/drain region(s) 204SD may refer to a source region or a drain region, individually or collectively dependent upon the context. Each of the channel regions 204C is disposed between two source/drain regions 204SD along the X direction.

The workpiece 200 also includes isolation features 205 (shown in FIG. 3C) formed around the fin-shaped active regions to isolate one fin-shaped active region from an adjacent fin-shaped active region. The isolation features 205 may include shallow trench isolation (STI) features 205. In an example process, a dielectric material for the isolation features 205 is first deposited over the workpiece 200, filling the trenches between the fin-shaped active regions 204A-204D with the dielectric material. In some embodiments, the dielectric material may include silicon oxide, silicon oxynitride, fluorine-doped silicate glass (FSG), a low-k dielectric, combinations thereof, and/or other suitable materials. In various examples, the dielectric material may be deposited by a CVD process, a flowable CVD (FCVD) process, spin-on coating, and/or other suitable process. The deposited dielectric material is then thinned and planarized, for example by a chemical mechanical polishing (CMP) process, until top surfaces of the fin-shaped active regions 204A-204D are exposed. The planarized dielectric material is further recessed or etched back by a dry etching process, a wet etching process, and/or a combination thereof to form the STI features 205. In embodiments represented in FIG. 3C, upper portions of the fin-shaped active regions 204A-204D rise above the STI features 205 while lower portions of the fin-shaped active regions 204A-204D remain covered or buried in the STI features 205. The deposited dielectric material may be a single-layer structure or a multi-layer structure. In the present embodiments, at least one of the STI features 205 includes a horizontal portion 205h extending between two adjacent fin-shaped active regions (e.g., the fin-shaped active regions 204B and 204C) and two vertical portions 205v extending along bottom sidewall surfaces of the two adjacent fin-shaped active regions.

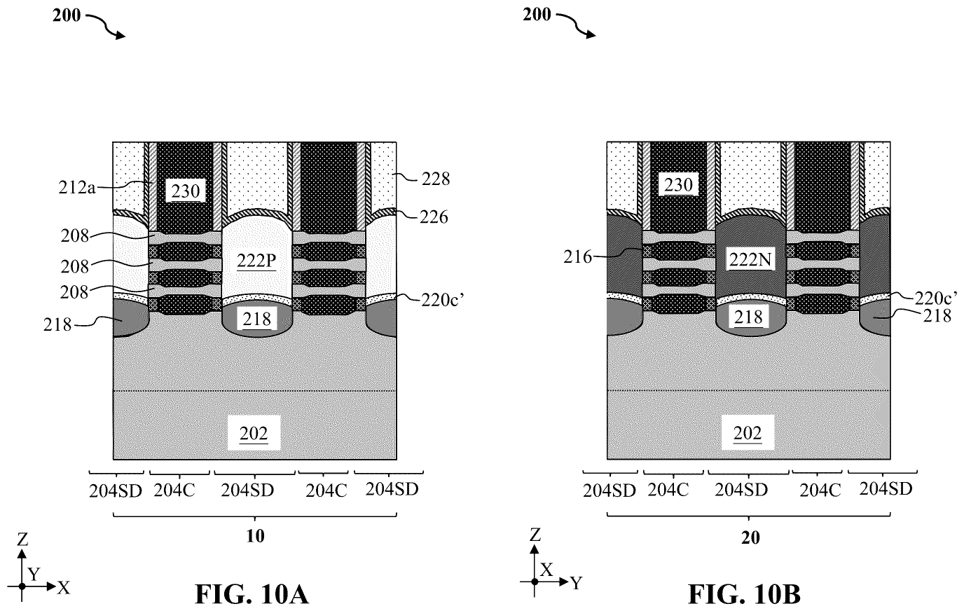

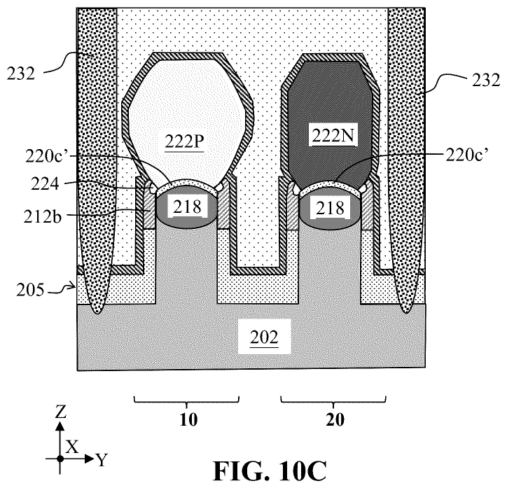

The workpiece 200 also includes dummy gate stack 210. Each of the dummy gate stacks 210 includes a dummy gate dielectric layer 210a, a dummy gate electrode layer 210b over the dummy gate dielectric layer 210a, a gate-top hard mask layer 210c over the dummy gate electrode layer 210b. The dummy gate dielectric layer 210a may include silicon oxide. The dummy gate electrode layer 210b may include polysilicon. The gate-top hard mask layer 210c may include silicon oxide layer, silicon nitride, and/or other suitable materials. Suitable deposition process, photolithography and etching process may be employed to form the dummy gate stacks 210. In this embodiment, a gate replacement process (or gate-last process) is adopted where the dummy gate stacks 210 serve as placeholders for functional gate structures (e.g., gate structures 230 shown in FIGS. 10A-10B). Other processes and configurations are possible. Three dummy gate stacks 210 are shown in FIG. 2, but the workpiece 200 may include any suitable number of dummy gate stacks 210.

The workpiece 200 also includes gate spacers 212a extending along sidewall surfaces of the dummy gate stacks 210. Each of the gate spacers 212a may be a single-layer structure or a multi-layer structure. In an example process, a first spacer layer (not separately labeled) is conformally deposited over the workpiece 200 and a second spacer (not separately labeled) layer is conformally deposited over the first spacer layer. The first spacer layer is conformally deposited over the workpiece 200, including the fin-shaped active regions 204A-204D, by atomic layer deposition (ALD), chemical vapor deposition (CVD), or any other suitable deposition process. The term “conformally” may be used herein for ease of description of a layer having substantially uniform thickness over various regions of the workpiece 200. The first spacer layer may include silicon oxide, silicon nitride, silicon oxycarbide, silicon oxycarbonitride, silicon carbonitride, metal nitride, or other suitable dielectric materials. In an embodiment, the first spacer layer includes silicon carbonitride (SiCN). After forming the first spacer layer, the second spacer layer is conformally deposited over the first spacer layer by ALD, CVD, or any other suitable deposition process. The second spacer layer may include silicon oxide, silicon nitride, silicon oxycarbide, silicon oxycarbonitride, silicon carbonitride, metal nitride, or other suitable dielectric materials. A composition of the first spacer layer is different from a composition of the second spacer layer to introduce etching selectivity. In an embodiment, the second spacer layer includes silicon nitride (SiN). After the formation of the first spacer layer and the second spacer layer, an etching process is performed to remove portions of the first spacer layer and the second spacer layer over top-facing surfaces of the workpiece 200 to form gate spacers 212a extending along sidewalls of the dummy gate stacks 210. The deposition and etching of the first spacer layer and the second spacer layer also forms fin sidewall spacers 212b (shown in FIG. 3C) extending along lower portions of sidewalls of the fin-shaped active regions 204A-204D and disposed on the vertical portions 205v of the STI features 205.

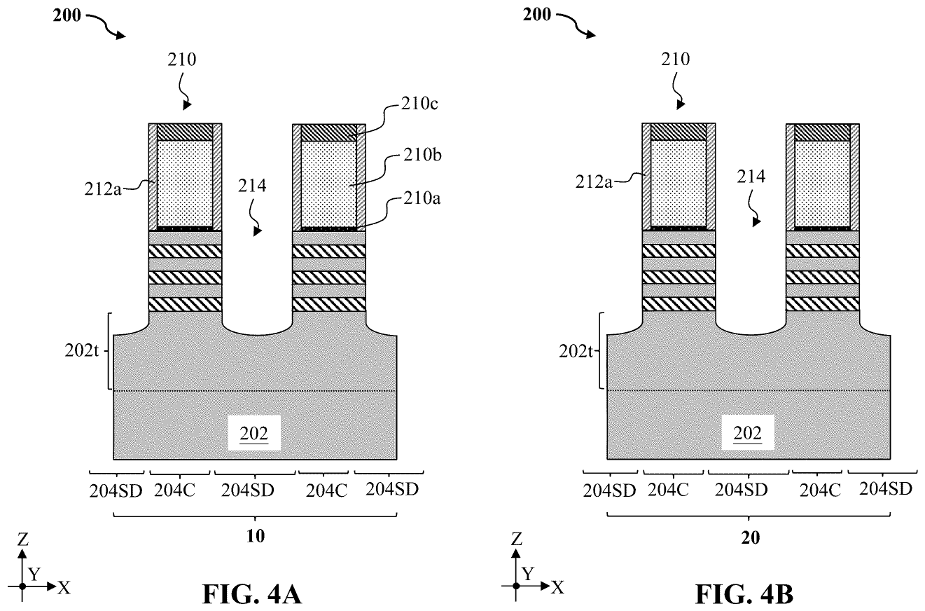

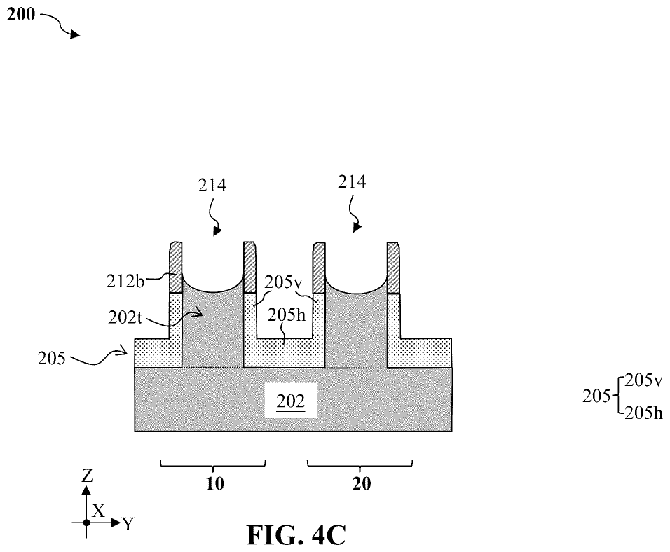

Referring to FIGS. 1 and 4A-4C, method 100 includes a block 104 where source/drain regions 204SD of the fin-shaped active regions 204A-204D are recessed to form source/drain openings 214. In some embodiments, the source/drain regions 204SD of the fin-shaped active regions 204A-204D are anisotropically etched by a plasma etch with a suitable etchant, such as fluorine-containing etchant, oxygen-containing etchant, hydrogen-containing etchant, a fluorine-containing etchant (e.g., CF₄, SF₆, CH₂F₂, CHF₃, and/or C₂F₆), a chlorine-containing etchant (e.g., Cl₂, CHCl₃, CCl₄, and/or BCl₃), a bromine-containing etchant (e.g., HBr and/or CHBr₃), an iodine-containing etchant, other suitable etchants, and/or combinations thereof. In the present embodiments, the source/drain openings 214 extend into the top portion 202t of the substrate 202.

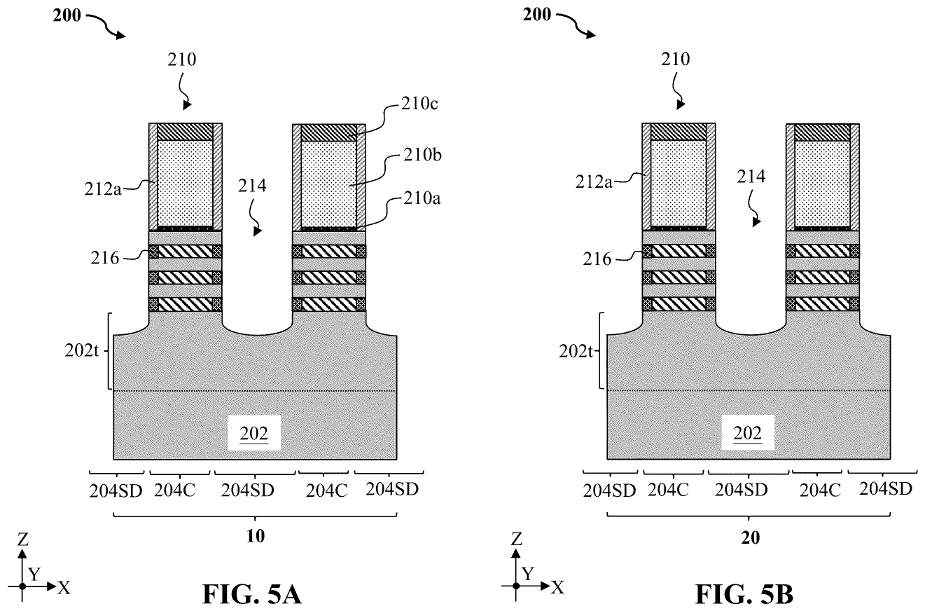

Referring to FIGS. 1 and 5A-5B, method 100 includes a block 106 where inner spacer features 216 are formed. After forming the source/drain openings 214 in the first region 10 and the second region 20, the sacrificial layers 206 exposed in the source/drain openings 214 are selectively and partially recessed to form inner spacer recesses (filled by inner spacer features 216), while the exposed channel layers 208 are substantially unetched. In some embodiments, this selective recess may include a selective isotropic etching process (e.g., a selective dry etching process or a selective wet etching process), and the extent at which the sacrificial layers 206 is recessed is controlled by duration of the etching process. After the formation of the inner spacer recesses, an inner spacer material layer is then conformally deposited using CVD or ALD over the workpiece 200, including over and into the inner spacer recesses. The inner spacer material may include silicon nitride, silicon oxycarbonitride, silicon carbonitride, silicon oxide, silicon oxycarbide, silicon carbide, or silicon oxynitride. The inner spacer material layer is then etched back to form the inner spacer features 216, as illustrated in FIGS. 5A-5B. In some embodiments, a composition of the inner spacer features 216 is different than a composition of the gate spacers 212a such that the etching back of the inner spacer material layer does not substantially etch the gate spacers 212a.

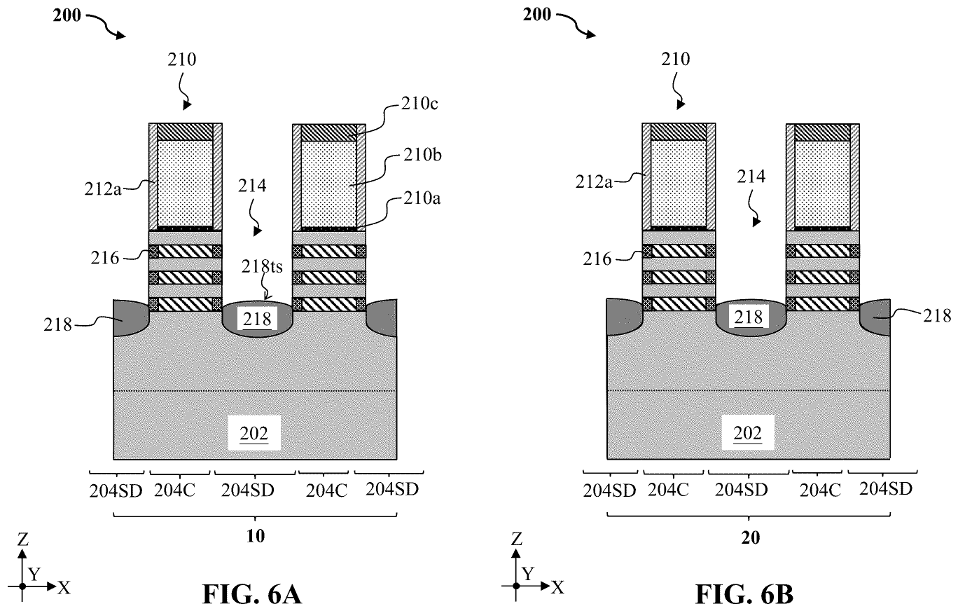

Referring now to FIGS. 1 and 6A-6B, method 100 includes a block 108 where semiconductor layers 218 are formed in the source/drain openings 214. In the present embodiments, after forming the inner spacer features 216, the semiconductor layers 218 are formed in the source/drain openings 214 by using an epitaxial process. Each of the semiconductor layers 218 may be undoped or not intentionally doped. In some embodiments, the semiconductor layers 218 may include undoped silicon (Si), undoped germanium (Ge), undoped silicon germanium (SiGe), or other suitable materials. In an embodiment, the semiconductor layers 218 are formed simultaneously by a common epitaxial process and include undoped silicon (Si). In this depicted example, the top surface 218ts of the semiconductor layer 218 is above the top surface 202ts of the substrate 202 and below the bottom surface of the bottommost channel layer of the number of channel layers 208 and has a convex profile.

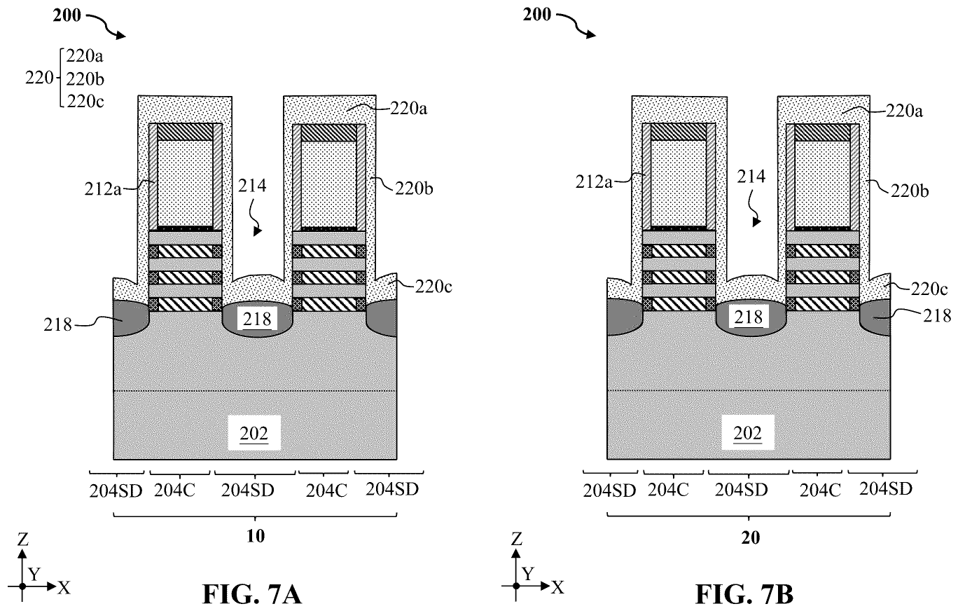

Referring now to FIGS. 1 and 7A-7B, method 100 includes a block 110 where an insulation layer 220 is deposited over the workpiece 200, including in the first region 10 and the second region 20. In the present embodiments, the insulation layer 220 is deposited by using a chemical vaper deposition (CVD), physical vaper deposition (PVD), atomic layer deposition (ALD) or other suitable processes, and the deposition thickness of the insulation layer 220 may be dependent on desired thicknesses of final bottom portions 220c′ of the insulation layer 220 formed in the source/drain openings 214. In an embodiment, the insulation layer 220 is deposited by using a physical vaper deposition (PVD) process. Due to the properties of the PVD process, a portion of the insulation layer 220 formed on a top or planar surface are thicker than a portion of the insulation layer 220 formed on a side surface. More specifically, as depicted in FIGS. 7A-7B, the insulation layer 220 includes a top portion 220a formed over top surfaces of the dummy gate stacks 210, a sidewall portion 220b extending along exposed sidewall surfaces of the channel regions 204C of the fin-shaped active regions, and a bottom portion 220c formed on the top surface of the semiconductor layers 218. For embodiments in which the insulation layer 220 is deposited by PVD, a thickness of the portion 220a/220c is greater than a thickness of the sidewall portion 220b. The insulation layer 220 may be formed of any suitable dielectric material so long as its composition is different from those of the channel layers (e.g., channel layers 208b, 208m, 208t), the sacrificial layers 206, and the gate-top hard mask layer 210c to allow selective removal by an etching process. In some embodiments, the insulation layer 220 may include silicon nitride (SiN), silicon oxycarbonitride (SiOCN), silicon carbonitride (SiCN), or other suitable materials.

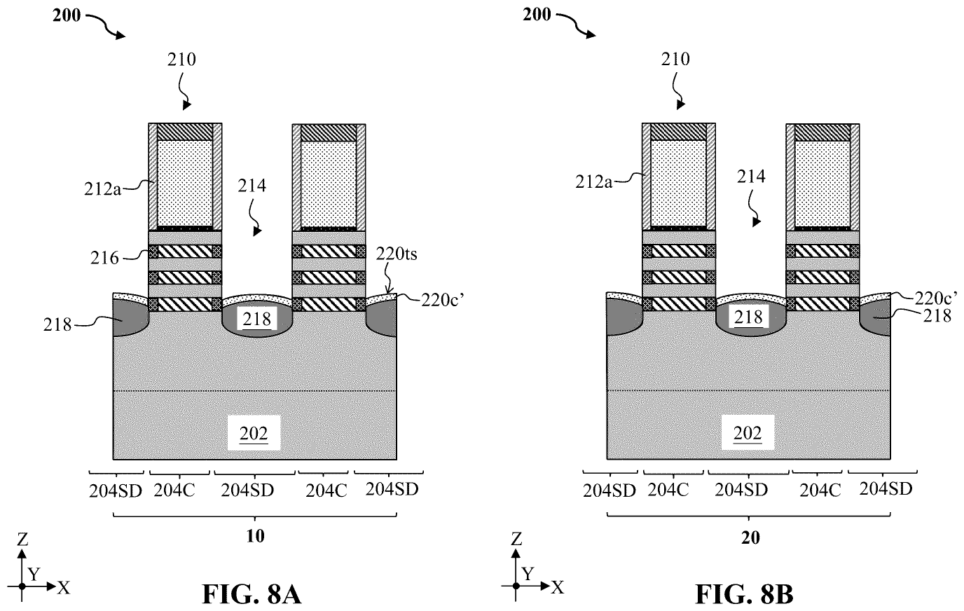

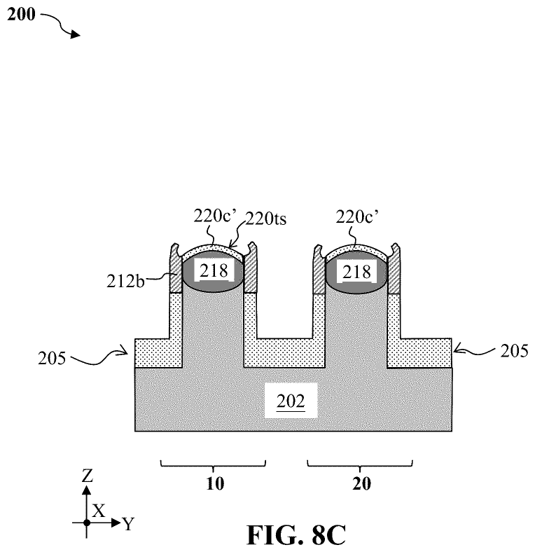

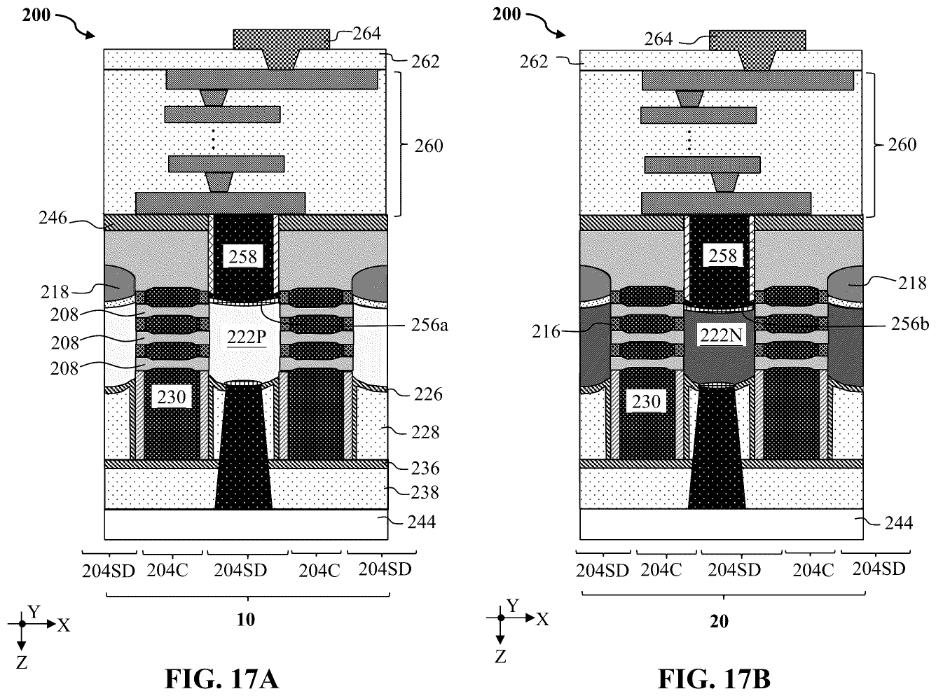

Referring now to FIGS. 1 and 8A-8C, method 100 includes a block 112 where portions of the insulation layer 220 are removed, thereby leaving bottom portions 220c of the insulation layer in the source/drain openings 214 and on the undoped semiconductor layers 218. In an example process, a mask layer (e.g., a bottom antireflective coating (BARC) layer) (not shown) is formed to cover the bottom portion 220c of the insulation layer 220 without covering other portions of the insulation layer 220. Since the mask layer has a thickness along the Z direction, it also covers a lower part of the sidewall portion 220b of the insulation layer 220. While using the mask layer as an etch mask, a first etching process is performed to selectively remove portions of the insulation layer 220 not covered by the mask layer. The mask layer may be then selectively removed using a suitable etching process. A second etching process may be followed to isotopically etch the remaining portion of the insulation layer 220 to remove the lower part of the sidewall portion 220b of the insulation layer 220, thereby leaving partially etched bottom portions 220c on the semiconductor layers 218. In some embodiments, the first and/or the second etching process may slightly etch the fin sidewall spacers 212b. The partially etched bottom portions 220c of the insulation layer 220 may be referred to as a dielectric layer 220c′. A top surface 220ts of the dielectric layer 220c′ is a convex top surface that substantially tracks the shape of the top surface of the semiconductor layer 218 disposed thereunder. In the present embodiments, the top surface of the dielectric layer 220c′ is below the top surface of the bottommost inner spacer feature 216 of the inner spacer features 216. That is, the dielectric layer 220c′ is not in direct contact with the bottommost one of the number of channel layers 208. In an embodiment, the dielectric layer 220c′ has a thickness in a range between about 1 nm and 5 nm. For embodiments in which a final structure of the workpiece 200 includes the dielectric layer 220c′, the formation of the dielectric layer 220c′ will substantially suppress and/or eliminate any parasitic transistor formed between the metal gate structures 230 (shown in FIG. 17), source/drain features 222N/222P, and underlying mesa structure(s) 202t, thereby reducing and/or blocking leakage current through the mesa structure(s) 202t. In addition to this, in the present embodiments, the formation of the dielectric layer 220c′ will facilitate the formation of an area-increased backside silicide layer.

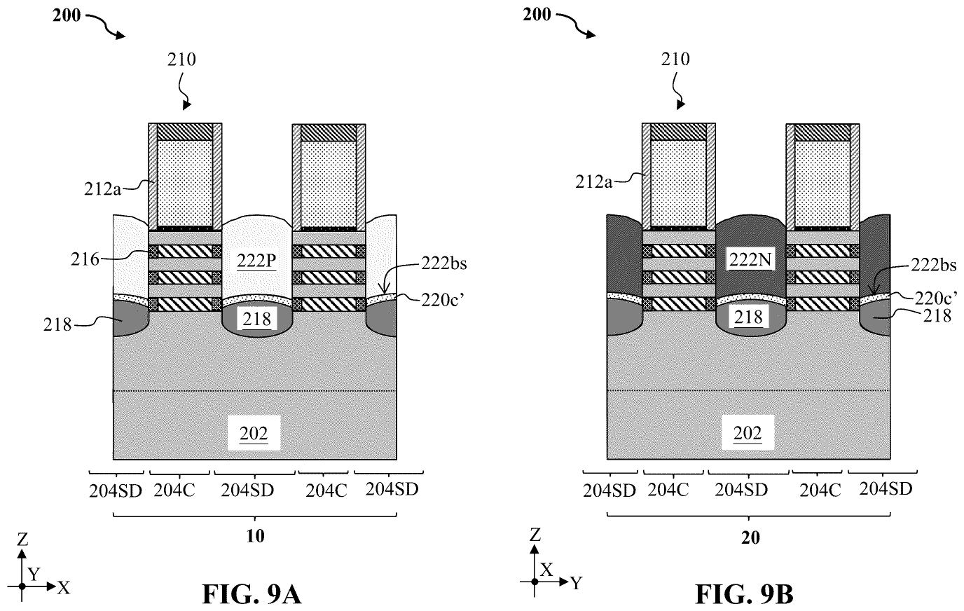

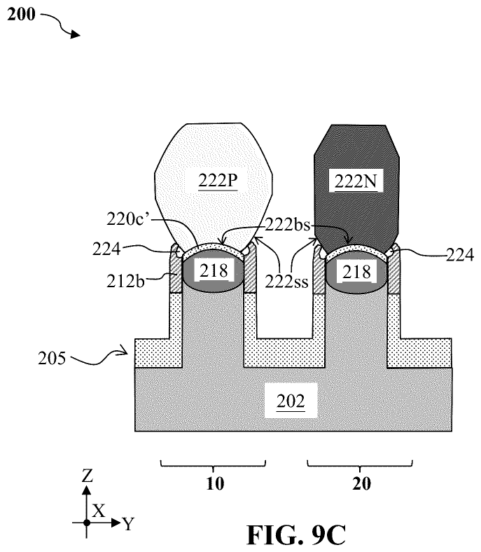

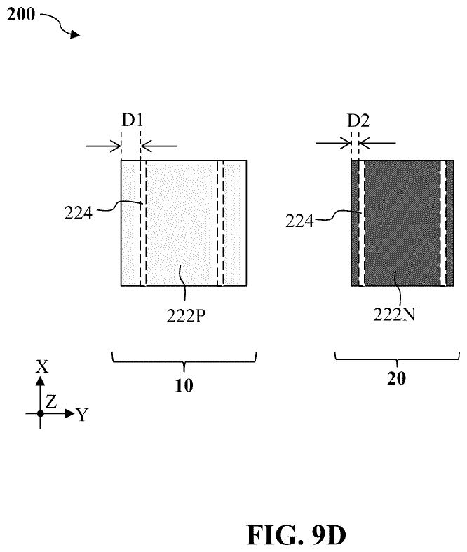

Referring now to FIGS. 1 and 9A-9D, method 100 includes a block 114 where source/drain features 222P and 222N are formed in the source/drain openings 214 in the first region 10 and the second region 20, respectively. Source/drain feature(s) may refer to a source or a drain, individually or collectively dependent upon the context. The source/drain features 222P are coupled to the channel layers 208 of the channel regions 204C in the first region 10. The source/drain features 222N are coupled to the channel layers 208 of the channel regions 204C in the second region 20. The source/drain features 222N and 222P each may be epitaxially and selectively formed from exposed sidewalls of the channel layers 208 by using an epitaxial process, such as vapor phase epitaxy (VPE), ultrahigh vacuum chemical vapor deposition (UHV-CVD), molecular-beam epitaxy (MBE), and/or other suitable processes.

Example N-type source/drain features 222N may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process. Example P-type source/drain features 222P may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. In some embodiments, each of the N-type source/drain features 222N and the P-type source/drain features 222P may include multiple semiconductor layers with different doping concentrations. The N-type source/drain features 222N and the P-type source/drain features 222P may be formed in any suitable sequential orders.

In the present embodiment, due to the presence of the dielectric layers 220c′, as depicted by FIGS. 9A-9B, the source/drain features 222P/222N cannot be epitaxially grown from the bottom up (i.e., along the Z direction) since the semiconductor layers 218 in the source/drain regions 204S/D are blocked by the dielectric layers 220c′ and cannot provide exposed semiconductor surfaces for the epitaxial growth. As depicted by FIG. 8C, when viewed from the X direction, the workpiece 200 in the fragmentary cross-sectional view does not provide any exposed semiconductor surfaces for direct epitaxial growth along the Y direction as well. Instead, the source/drain features 222N and 222P are epitaxially formed from exposed sidewalls of the channel layers 208 along the X direction until semiconductor layers of the source/drain features are merged. The incapability of being epitaxially grown from the bottom up and the incapability of being epitaxially grown along the Y direction lead to formation of voids 224 (or air gaps 224) enclosed by the source/drain features 222N/222P, the dielectric layers 220c′, and the fin sidewall spacers 212b, as depicted by FIG. 9C. More precisely, the void 224 is defined by the top surface of the dielectric layer 220′, a sidewall surface 222ss of the source/drain feature 222N/222P, and the fin sidewall spacer 212b. The sidewall surface 222ss curves upward and outward. That is, a portion of the top surface 220ts of the dielectric layer 220′ is not in direct contact with the bottom surface 222bs of the source/drain feature 222N/222P. It is noted that, in the cross-sectional view represented by FIGS. 9A-9B, the workpiece 200 does not include voids formed between the source/drain features 222N/222P and the dielectric layers 220c′, and bottom surfaces 222bs of the source/drain features 222N/222P track the shapes of the dielectric layers 220c′ thereunder. FIG. 9D depicts top views of the P-type source/drain feature 222P and the N-type source/drain feature 222N. Each of the voids 224 extends lengthwise along the X direction. In an embodiment, in the top view, a distance D1 between the void 224 in the first region 10 and a nearest edge of the P-type source/drain feature 222P is greater than a distance D1 between the void 224 in the second region 20 and a nearest edge of the N-type source/drain feature 222N. In an embodiment, the void 224 spans a width along the Y direction and a height along the Z direction, the width may be in a range between about 3 nm and 10 nm, and the height may be in a range between about 3 nm and about 10 nm.

Referring now to FIGS. 1 and 10A-10C, method 100 includes a block 116 where the dummy gate stacks 210 and the sacrificial layers 206 are replaced by metal gate structures 230. A contact etch stop layer (CESL) 226 and a first interlayer dielectric (ILD) layer 228 are deposited over the workpiece 200. The CESL 226 may include silicon nitride, silicon oxynitride, and/or other suitable materials and may be formed by ALD, plasma-enhanced chemical vapor deposition (PECVD) process and/or other suitable deposition or oxidation processes. The first ILD layer 228 is deposited by a PECVD process or other suitable deposition technique over the workpiece 200 after the deposition of the CESL 226. The first ILD layer 228 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A planarization process, such a chemical mechanical polishing (CMP) process may be performed to the workpiece 200 to remove excess materials and expose top surfaces of the dummy gate electrode layers 210b in the dummy gate stacks 210. A first etching process may be implemented to selectively remove the dummy gate electrode layers 212 and the dummy gate dielectric layers 211 of the dummy gate stacks 210 without substantially removing the gate spacers 212a to form gate trenches in the first region 10 and the second region 20. After the removal of the dummy gate stacks 210, the sacrificial layers 206 in the channel regions 204C are selectively removed to release the channel layers 208 as channel members 208. The selective removal of the sacrificial layers 206 forms gate openings under the gate trenches.

After the removal of the dummy gate stacks 210 and the sacrificial layers 206, metal gate structures 230 are formed in the gate trenches and openings in the first region 10 and the second region 20. The formation of the metal gate structure 230 includes forming an interfacial layer to wrap around and over each of the channel members 208. The interfacial layer may include silicon oxide or other suitable material. The interfacial layer may be formed using a suitable method, such as atomic layer deposition (ALD), chemical vapor deposition (CVD), thermal oxidation, or other suitable method. In an embodiment, the interfacial layer is formed by thermal oxidation and is thus only formed on surfaces of the channel members 208. That is, the interfacial layer does not extend along sidewall surfaces of the gate spacers 212a and does not extend along sidewall surfaces of the inner spacer features 216. In another embodiment, the interfacial layer is formed by ALD and is thus conformally formed on surfaces of the workpiece 200. That is, the interfacial layer also extends along sidewall surfaces of the gate spacers 212a and sidewall surfaces of the inner spacer features 216. After forming the interfacial layer, a dielectric layer is formed over the workpiece 200 to wrap around and over each of the channel members 208. In an embodiment, the dielectric layer is deposited conformally over the workpiece 200. The term “conformally” may be used herein for ease of description of a layer having a substantially uniform thickness over various regions. In some embodiments, the dielectric layer is high-k dielectric layer as its dielectric constant is greater than that of silicon dioxide (˜3.9). In some implementations, the dielectric layer may include titanium oxide (TiO₂), tantalum oxide (Ta₂O₅), hafnium silicon oxide (HfSiO₄), zirconium oxide (ZrO₂), zirconium silicon oxide (ZrSiO₂), aluminum oxide (Al₂O₃), zirconium oxide (ZrO), yttrium oxide (Y₂O₃), SrTiO₃ (STO), BaTiO₃ (BTO), BaZrO, aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The dielectric layer and the interfacial layer may be collectively referred to as a gate dielectric layer.

The formation of the metal gate structure 230 also includes forming a gate electrode over the gate dielectric layer. The gate electrode may be a multi-layer structure that includes at least one work function layer and a metal fill layer. By way of example, the at least one work function layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), or tantalum carbide (TaC). The metal gate structure 230 formed in the first region 10 may include at least a P-type work function layer. The P-type work function layer may include titanium nitride (TiN), tungsten carbonitride (WCN), tantalum nitride (TaN), or molybdenum nitride (MoN). The metal gate structure 230 formed in the second region 20 may include at least an N-type work function layer. The N-type work function layer may include titanium-aluminum based metal, such as titanium aluminum carbon (TiAlC) or titanium aluminum (TiAl). The metal fill layer may include aluminum (Al), tungsten (W), nickel (Ni), titanium (Ti), ruthenium (Ru), cobalt (Co), platinum (Pt), tantalum silicon nitride (TaSiN), copper (Cu), other refractory metals, or other suitable metal materials or a combination thereof. In various embodiments, the gate electrode may be formed by ALD, PVD, CVD, e-beam evaporation, or other suitable process. In various embodiments, a planarization process, such as a chemical mechanical polishing (CMP) process, may be performed to remove excess materials over the first ILD layer 228 to provide a substantially planar top surface and facilitate the performing of further processes.

In some embodiments, after forming the metal gate structures 230, gate isolation structures (e.g., gate isolation structures 232) may be formed to cut one or more of the metal gate structures 230 into physically and electrically isolated segments. When viewed from top, the gate isolation structures 232 extend lengthwise along a direction (e.g., X direction) parallel to that of the fin-shaped active regions 204A-204C. The gate isolation structures 232 extend into the STI features 205 and may be formed of any suitable dielectric materials.

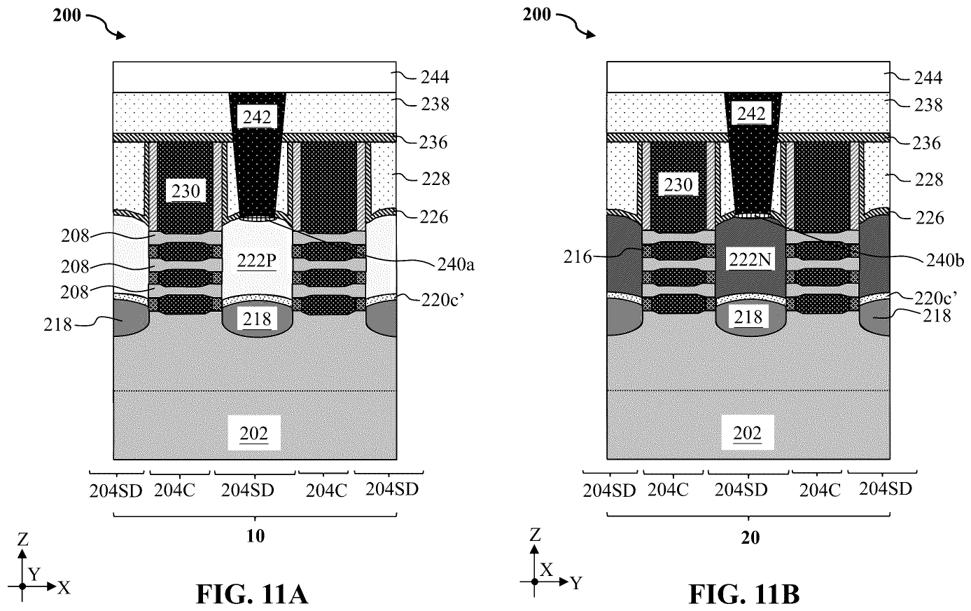

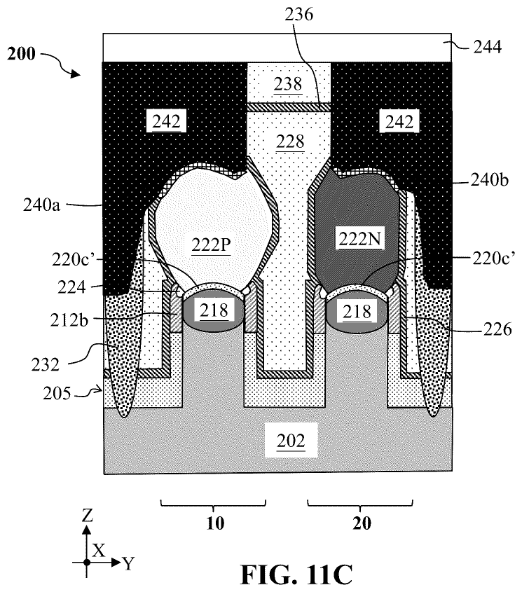

Referring to FIGS. 1 and 11A-11C, method 100 includes a block 118 where silicide layers 240a/240b and source/drain contacts 242 are formed over front side of the substrate 202. In an example process, an etch stop layer 236 and a second ILD layer 238 are deposited over the workpiece 200. The etch stop layer 236 may be similar to the contact etch stop layer 226 and the second ILD layer 238 may be similar to the first ILD layer 228 in terms of composition and formation processes. The etch stop layer 236 may indicate an etch stop point for forming gate via openings over the metal gate structures 230. Source/drain contact openings (now filled by silicide layers 240a/240b and source/drain contacts 242) are formed to expose the p-type source/drain features 222P and/or the n-type source/drain feature 222N using a combination of photolithography processes and etch processes. In an example process, a hard mask layer and a photoresist are deposited over the workpiece 200. The photoresist layer is then exposed to a patterned radiation transmitting through or reflected from a photo mask, baked in a post-exposure bake process, developed in a developer solution, and then rinsed, thereby forming a patterned photoresist layer. The patterned photoresist layer is then applied as an etch mask to etch the hard mask layer to form a patterned hard mask layer. The patterned hard mask layer is then applied as an etch mask to etch the second ILD layer 238, the etch stop layer 236, the first ILD layer 228, and the CESL 226. The etch process for etching the second ILD layer 238, the first ILD layer 228, and the CESL 226 may be a dry etch process that includes use of argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, or combinations thereof.

After forming the source/drain contact openings, silicide layers 240a/240b and source/drain contacts 242 are formed therein. To form the silicide layers 240a/240b, a metal precursor (e.g., titanium, tantalum, nickel, cobalt, or tungsten) is deposited over the workpiece, including on the exposed surface of the n-type source/drain feature 222N and the exposed surface of the p-type source/drain feature 222P. An anneal process is then performed to bring about silicidation in the second region 20 and germinidation in the first region 10 between the metal precursor and the exposed semiconductor surfaces. In some embodiments, the unreacted metal precursor is selectively removed after the formation of the silicide layers 240a-240b. For embodiments in which the metal precursor includes nickel, nickel may react with silicon germanium in the p-type source/drain feature 222P to form the silicide layer 240a and may react with silicon in the n-type source/drain feature 222N to form the silicide layer 240b. Accordingly, the silicide layers 240a may include nickel silicide, and the silicide layer 240b includes nickel silicide, nickel germanide, and nickel germanosilicide.

A conductive layer is then deposited over the workpiece 200, including in the source/drain contact openings and on the silicide layers 240a-240b. The conductive layer may include aluminum (Al), copper (Cu), tungsten (W), cobalt (Co), ruthenium (Ru), or molybdenum (Mo) or other suitable materials and may be formed by any suitable deposition processes (e.g., CVD). A planarization process, such as a chemical mechanical polish (CMP) process, may be then performed to remove excess portions of the conductive layer to form the source/drain contacts 242. After the performing of the planarization process, top surfaces of the source/drain contacts 242 are coplanar with the second ILD layer 238. Although not shown, in some embodiments, dielectric barrier layers may be formed to extend along sidewall surfaces of the source/drain contacts 242. In the cross-sectional view depicted in FIG. 11C, the source/drain contact 242 also extends into the gate isolation structure 232.

After forming the silicide layers 240a and 240b and source/drain contacts 242, other features such as gate vias and an interconnect structure 244 may be formed over the workpiece 200. In some embodiments, the interconnect structure 244 may include multiple intermetal dielectric (IMD) layers and multiple metal lines or contact vias in each of the IMD layers. In some instances, the IMD layers and the first ILD layer 228 may share similar composition. The metal lines and contact vias in each IMD layer may be formed of metal, such as aluminum, tungsten, ruthenium, or copper. In some embodiments, the metal lines and contact vias may be lined by a barrier layer to insulate the metal lines and contact vias from the IMD layers and to prevent electro-migration. Because the interconnect structure 244 is formed over the front side of the workpiece 200, the interconnect structure 244 may also be referred to as a frontside interconnect structure 244.

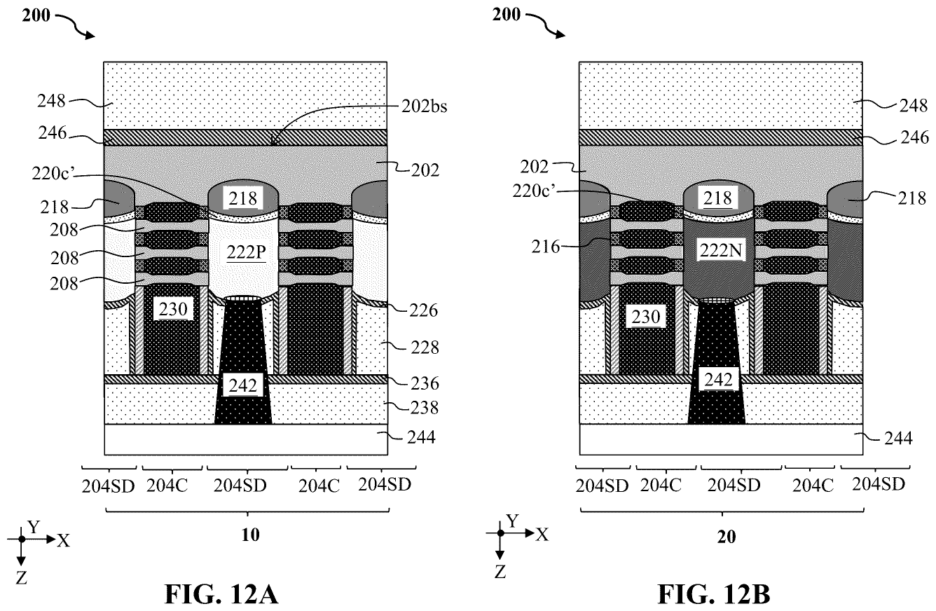

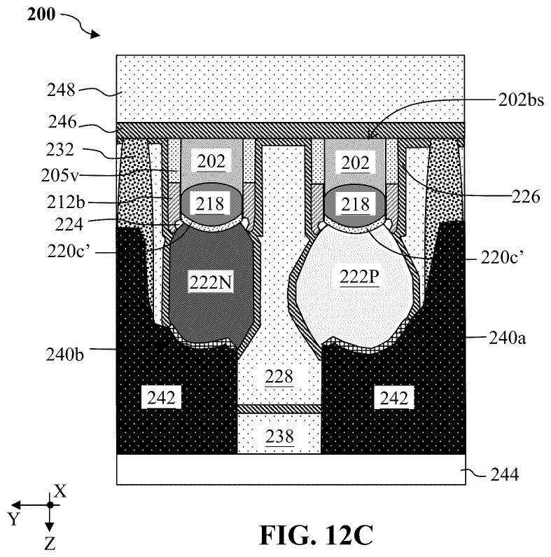

Referring to FIGS. 1 and 12A-12C, method 100 includes a block 120 where a thickness of the substrate 202 is reduced from its back. In an embodiment, a carrier substrate (not shown) is bonded to the interconnect structure 244. In some embodiments, the carrier substrate may be bonded to the workpiece 200 by fusion bonding, by use of an adhesion layer, or a combination thereof. In some instances, the carrier substrate may include semiconductor materials (such as silicon), sapphire, glass, polymeric materials, or other suitable materials. In embodiments where fusion bonding is used, the carrier substrate includes a bottom oxide layer and the interconnect structure 244 includes a top oxide layer. After both the bottom oxide layer and top oxide layer are treated, they are placed in plush contact with one another for direct bonding at room temperature or at an elevated temperature. Once the carrier substrate is bonded to the interconnect structure 244 of the workpiece 200, the workpiece 200 is flipped over. The back side of the workpiece 200 is then planarized to reduce a thickness of the substrate 202 from its back. In an embodiment, as depicted by FIG. 12C, after the planarization, the bottom surface 202bs of the substrate 202 is coplanar with a portion of the CESL 226 disposed between two fin-shaped active regions. The planarization process also removes the horizontal portion 205h of the STI features 205 and the portions of the gate isolation structures 232 extended into the STI features 205. For ease of description, the positional relationships hereafter will be described based on the workpiece 200 after the flipping, as depicted in the figures.

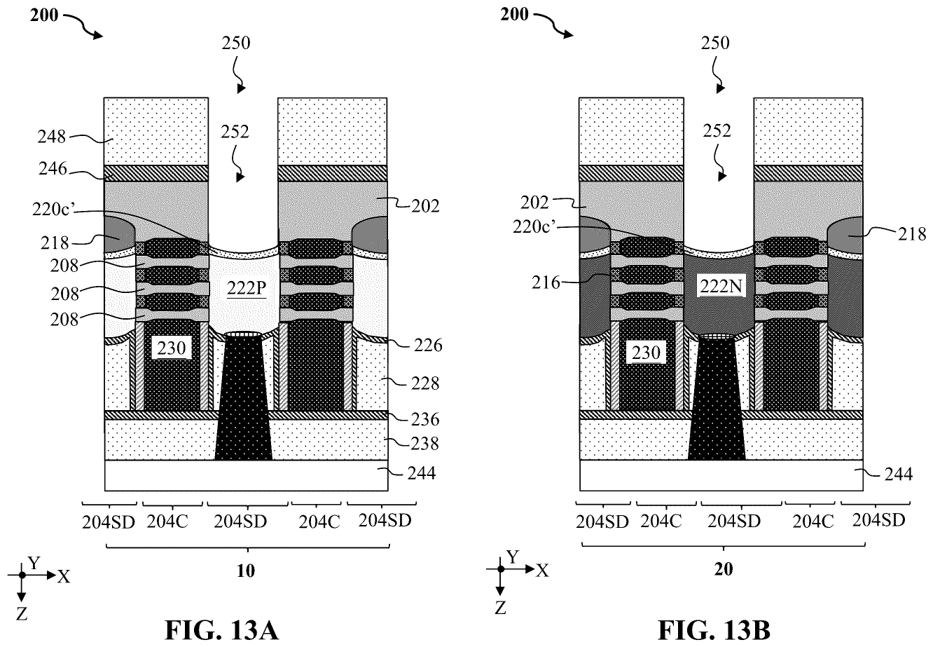

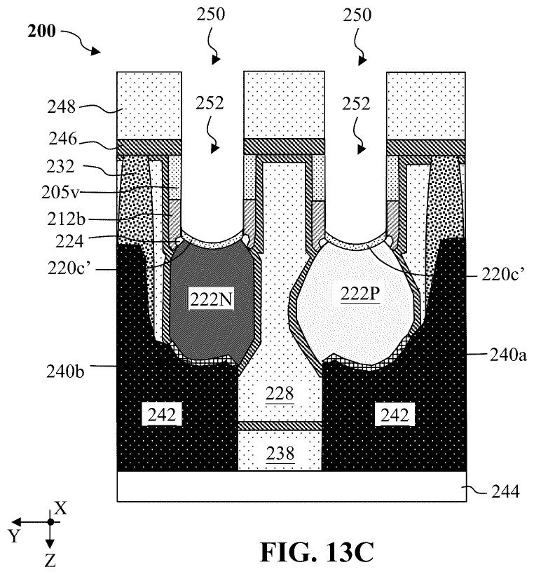

Referring to FIGS. 1, 12A-12C and 13A-13C, method 100 includes a block 122 where the semiconductor layer 218 and a portion of the substrate 202 disposed directly thereunder are removed to form a trench. In embodiment represented by FIGS. 12A-12C, a hard mask layer 246 and an oxide layer 248 are formed over the bottom surface 202bs of the planarized substrate 202. A thickness of the oxide layer 248 may be in a range between about 15 nm and about 45 nm, and a thickness of the hard mask layer 246 may be in a range between about 5 nm and 15 nm. The hard mask layer 246 and oxide layer 248 are then patterned to form an opening 250 directly over the semiconductor layer 218. While using the patterned oxide layer 248 and the patterned hard mask layer 246 as an etch mask, as depicted in FIGS. 13A-13C, an etching process is performed to selectively remove a portion of the substrate 202 exposed by the opening and the semiconductor layer 218 disposed directly under this portion of the substrate 202 to form the trench 252. In this embodiment, each of the first region 10 and the second region 20 includes a corresponding trench 252. The trench 252 exposes the dielectric layer 220c′. The etching process may be selective wet etching process or a selective dry etching process. An exemplary selective dry etching process may implement CF₄, NF₃, Cl₂, HBr, other suitable gases and/or plasmas, and/or combinations thereof.

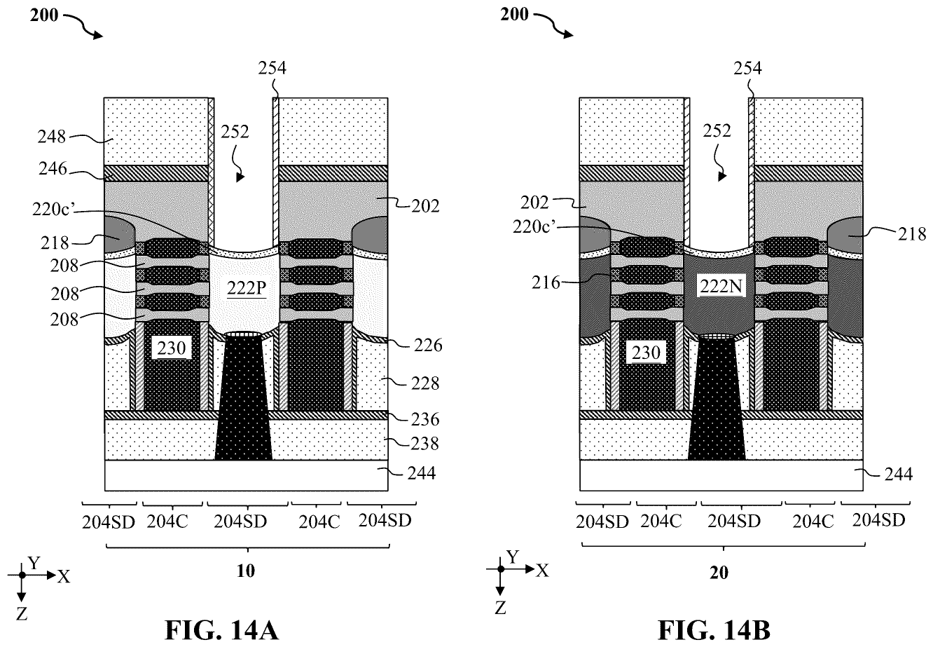

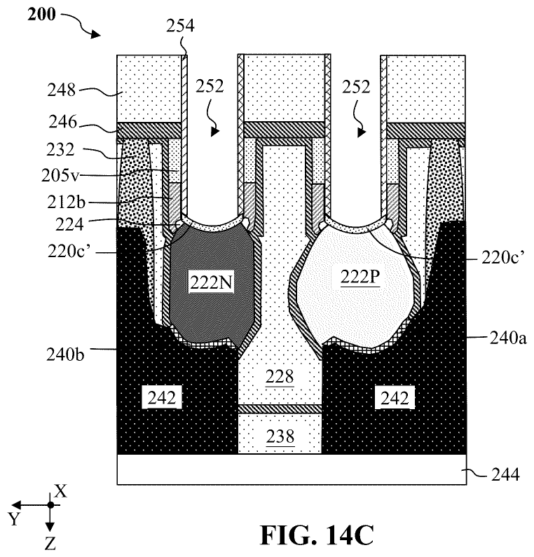

Referring to FIGS. 1 and 14A-14C, method 100 includes a block 124 where a dielectric barrier layer 254 is formed to extend along a sidewall surface of the trench 252. After the formation of the trench 252, in the present embodiments, to prevent surfaces of the substrate 202 exposed by the trench 252 from subsequent silicidation process, a dielectric barrier layer 254 is formed to extend along a sidewall surface of the trench 252. In an example process, a dielectric layer is conformally deposited over the workpiece 200 and is then etched back to only keep portions that extend along sidewall surface of the trenches 252, thereby forming the dielectric barrier layer 254. The bottom surface of the dielectric barrier layer 254 is in direct contact with the dielectric layer 220c′ and tilts inward and downward due to the profile of the dielectric layer 220c′. A composition of the dielectric barrier layer 254 is different from a composition of the dielectric layer 220c′ such that the dielectric layer 220c′ may be selectively removed afterwards. In some embodiments, the dielectric barrier layer 254 may include silicon nitride, silicon oxide, or other suitable materials.

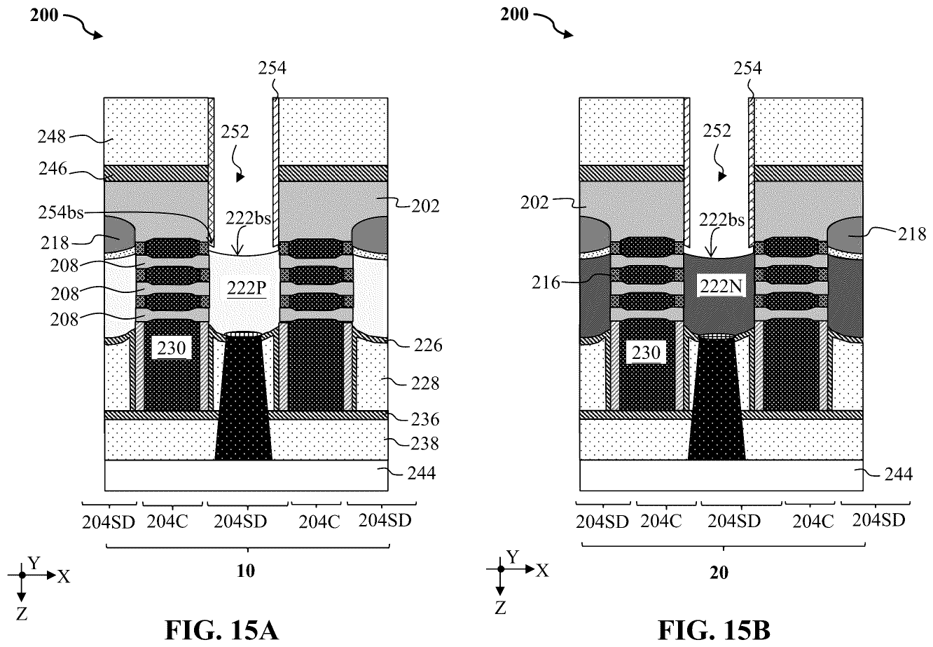

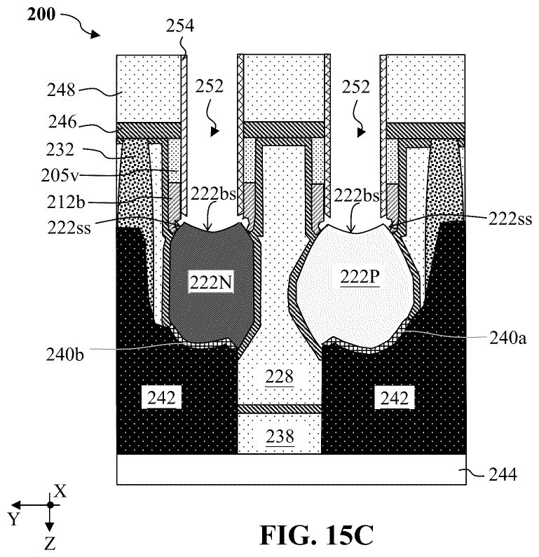

Referring to FIGS. 1 and 15A-15C, method 100 includes a block 126 where the dielectric layer 220c′ exposed by the trench 252 is selectively removed. After the formation of the dielectric barrier layer 254, while still using the patterned hard mask layer 246 and the patterned oxide layer 248 as an etch mask, an etching process is performed to selectively remove the dielectric layer 220c′ exposed by the trench 252 without substantially etching the dielectric barrier layer 254 and the source/drain feature 222N/222P to vertically extend the trench 252. As illustrated in FIGS. 15A-15B, the removal of the dielectric layer 220c′ exposes bottom surfaces 254bs of the dielectric barrier layer 254 and sidewall surfaces of inner spacer features 216 adjacent to the dielectric barrier layer 254. As represented by FIG. 15C, since the void 224 was enclosed by a combination of the dielectric layer 220c′, a part of the sidewall surface 222ss of the source/drain feature 222N/222P, and the fin sidewalls spacer 214b, the removal of the dielectric layer 220c′ breaks this enclosure and releases the part of the sidewall surface 222ss of the source/drain feature 222N/222P. As a result, the trench 252 now exposes not only the bottom surface 222bs of the source/drain feature 222N/222P, but also the part of the sidewall surface 222ss of the source/drain feature 222N/222P. That is, the trench 252 is also laterally expanded along the Y direction. The trench 252 after the removal of the dielectric layer 220c′ may be referred to as a backside contact opening 252.

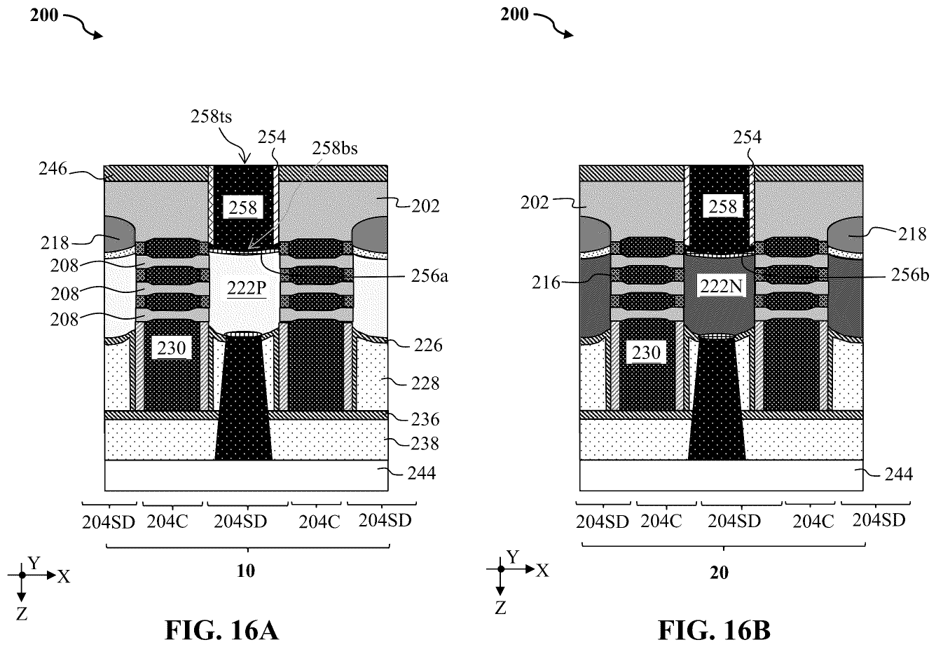

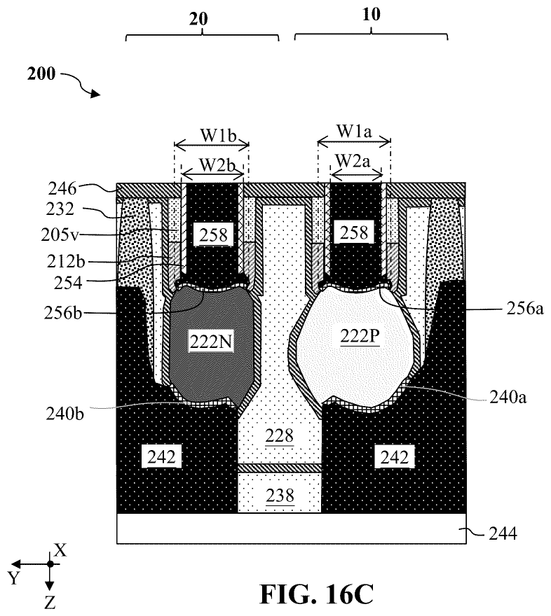

Referring to FIGS. 1 and 16A-16C, method 100 includes a block 128 where a conformal silicide layer 256a/256b and a backside source/drain contact 258 are formed in the backside contact opening 252. After forming backside contact opening 252, silicide layer 256a/256b and source/drain contact 258 are formed therein. To form the silicide layer 256a/256b, a metal precursor (e.g., titanium, tantalum, nickel, cobalt, or tungsten) is conformally deposited over the back side of the workpiece 200, including on the exposed bottom surface 222bs and the part of the exposed sidewall surface 222ss of the n-type source/drain feature 222N and the exposed bottom surface 222bs and the part of the exposed sidewall surface 222ss of the p-type source/drain feature 222P. An anneal process is then performed to bring about silicidation in the second region 20 and germinidation in the first region 10 between the metal precursor and the exposed semiconductor surfaces. In some embodiments, the unreacted metal precursor is selectively removed after the formation of the silicide layers 256a-256b. For embodiments in which the metal precursor includes nickel, nickel may react with silicon germanium in the p-type source/drain feature 222P to form the silicide layer 256a in the first region 10 and may react with silicon in the n-type source/drain feature 222N to form the silicide layer 256b in the second region 20.

In the cross-sectional view depicted by FIGS. 16A-16B, the silicide layer 256a has a portion disposed directly under the dielectric barrier layer 254 in the first region 10, and the silicide layer 256b has a portion disposed directly under the dielectric barrier layer 254 in the second region 20. In the cross-sectional view depicted by FIGS. 16C, the silicide layer 256a also has a portion that is in direct contact with the part of the exposed sidewall surface 222ss of the p-type source/drain feature 222P and disposed directly under the vertical portion 205v of the STI feature 205. Similarly, the silicide layer 256b also has a portion that is in direct contact with the part of the exposed sidewall surface 222ss of the n-type source/drain feature 222N and disposed directly under the vertical portion 205v of the STI feature 205. Thus, contact area between the silicide layer 256a/256b and the source/drain feature 222P/222N is increased, which advantageously reduce the parasitic resistance of the workpiece 200.

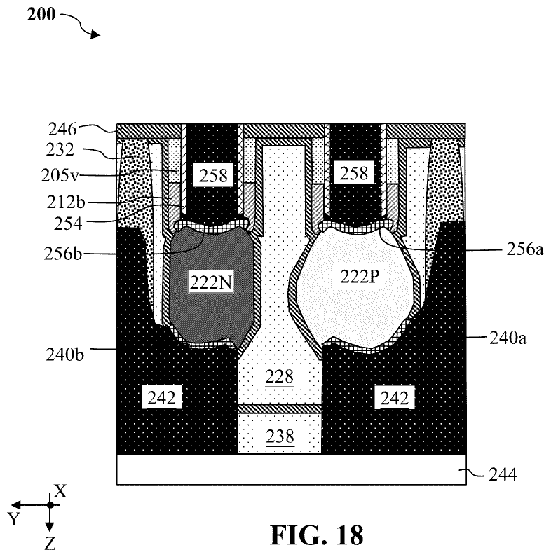

A conductive layer is then deposited over the back side of workpiece 200, including in the backside contact opening 252 and on the silicide layers 256a-256b. The conductive layer may include aluminum (Al), copper (Cu), tungsten (W), cobalt (Co), ruthenium (Ru), or molybdenum (Mo) or other suitable materials and may be formed by any suitable deposition processes (e.g., CVD). A planarization process, such as a chemical mechanical polish (CMP) process, may be then performed to remove excess materials over the patterned hard mask layer 246 to define a final structure of the backside source/drain contact 258. The backside source/drain contact 258 has a planar top surface 258ts that is coplanar with the top surface of the patterned hard mask layer 246 and a bottom surface 258bs in direct contact with the silicide layer 256a/256b thereunder. As illustrated in FIG. 16C, in the first region 10, the silicide layer 256a spans a width W1a along the Y direction, the planar top surface 258ts spans a width W2a along the Y direction, and W1a is greater than W2a; in the second region 20, the silicide layer 256b spans a width W1b along the Y direction, the planar top surface 258ts spans a width W2b along the Y direction, and W1b is greater than W2b. Depending on the size of the void 224, the conducive layer for forming the backside source/drain contact 258 may also fill a portion of the void 224. In embodiments represented by FIG. 16C, the backside source/drain contact 258 has a portion formed in the void 224 and disposed directly under the vertical portion 205V of the STI 205 and a portion disposed directly under the dielectric barrier layer 254. In an alternative embodiment represented by FIG. 18, for embodiments in which the void 224 has a smaller volume, the silicide layer 256a/256b substantially fills the void 224. In such embodiments, the silicide layer 256a/256b spans a width greater than that of the backside source/drain contact 258 formed thereon. In some embodiments, by adjusting the epitaxial growth recipe (e.g., adjusting the annealing temperature), the volume of the void 224 may be adjusted.

Referring to FIGS. 1 and 17A-17B, method 100 includes a block 130 where further processes are performed. Such further processes may include forming an interconnect structure 260 over the top surfaces 258ts of the backside source/drain contacts 258. In some embodiments, the interconnect structure 260 may include a multiple intermetal dielectric (IMD) layers and multiple metal lines or contact vias in each of the IMD layers. In some instances, the IMD layers and the first ILD layer 228 may share similar composition. The metal lines and contact vias in each IMD layer may be formed of metal, such as aluminum, tungsten, ruthenium, or copper. In some embodiments, the metal lines and contact vias may be lined by a barrier layer to insulate the metal lines and contact vias from the IMD layers and to prevent electro-migration. Because the interconnect structure 260 is formed over the back side of the workpiece 200, the interconnect structure 260 may also be referred to as a backside interconnect structure 260. Such further processes may also include forming a passivation structure 262 over the backside interconnect structure 260 and I/O 264 pads (e.g., aluminum pads) extending through the passivation structure to electrically connect to conductive features (e.g., metal lines) of the interconnect structure 260.

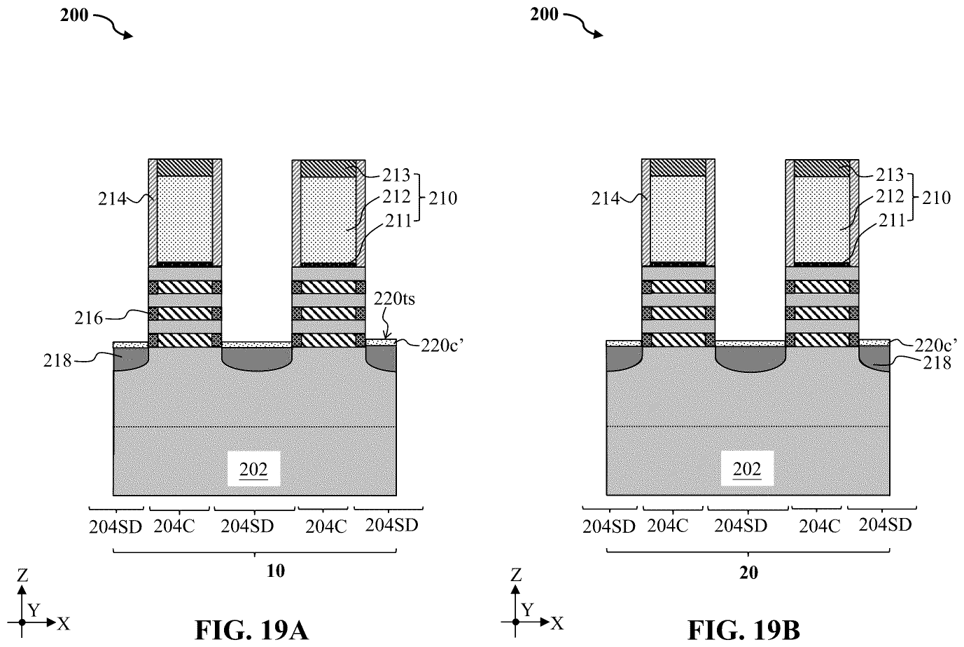

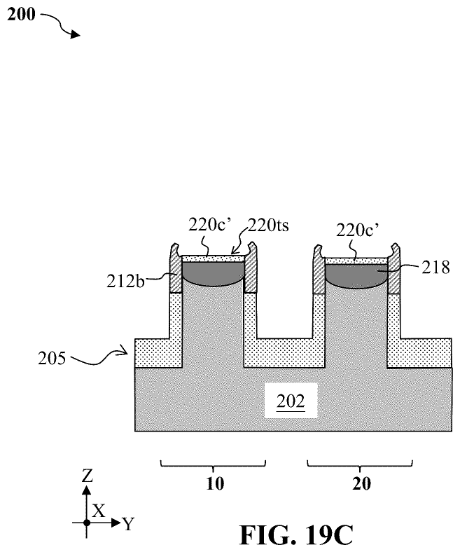

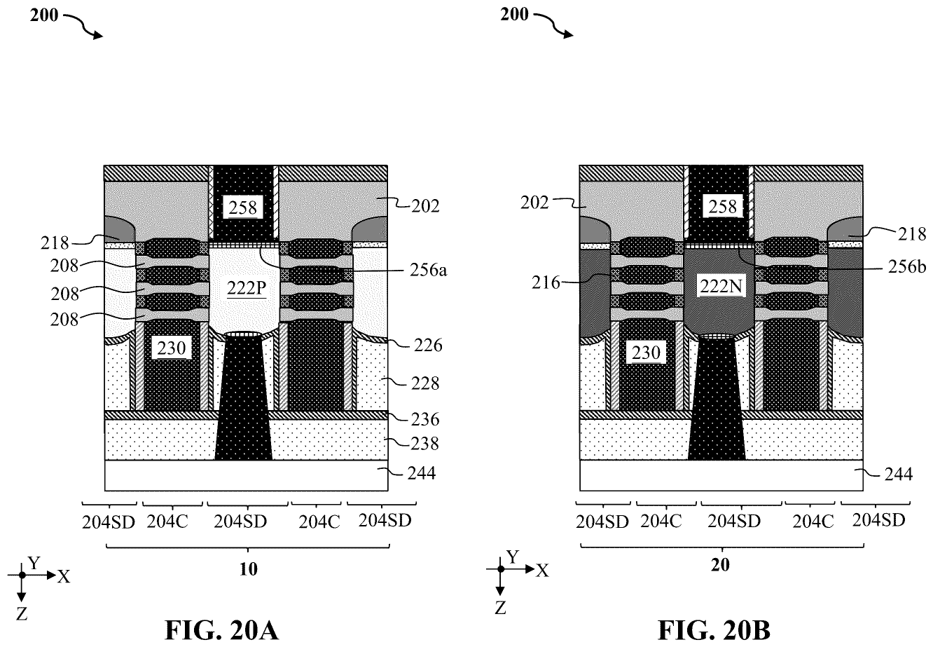

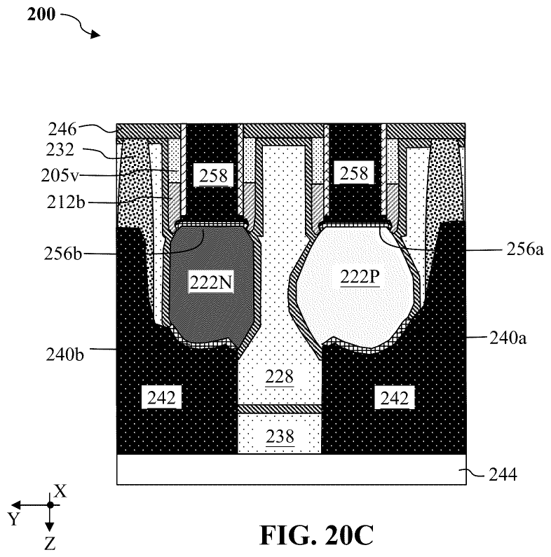

In the above embodiments, after performing operations in blocks 108-112, the dielectric layer 220c′ has a convex top surface 220ts (FIG. 8A), and the source/drain feature 222N/222P formed on the dielectric layer 220c′ has a bottom surface tracking the shape of the top surface 220ts of the dielectric layer 220c′. In some other embodiments, the dielectric layer 220c′ may have different profiles. FIGS. 19A-19C and FIGS. 20A-20C depict cross-sectional views of a first alternative workpiece during various fabrication stages in the method of FIG. 1, according to one or more aspects of the present disclosure. The first alternative workpiece 200 represented by FIGS. 19A-19C is similar to the workpiece 200 represented by FIGS. 8A-8C, and differences between these two workpieces include the different profiles of the top surface of the semiconductor layer 218 and the dielectric layer 220c′ formed on the semiconductor layer 218. The profile of the top surface of semiconductor layer 218 may be adjusted by the duration of the epitaxial growth process for forming the semiconductor layer 218. In this alternative embodiment, by performing a shorter duration of epitaxial growth process than that of the semiconductor layer 218 shown in FIG. 8A, the top surface of the semiconductor layer 218 is substantially coplanar with the bottom surface of the bottommost inner spacer feature 216. The dielectric layer 220c′ tracks the shape of the top surface of the semiconductor layer 218 and thus has a planar top surface and a planar bottom surface. Operations in blocks 114-130 may be then performed to form final structure of the workpiece according to this alternative embodiment. The resulted workpiece shown in FIGS. 20A-20C is similar to the workpiece 200 represented by FIGS. 16A-16C, and differences between these two workpieces include the different profiles of the silicide layers 256a-256b and the backside source/drain contact 258. More specifically, the portions of the silicide layers 256a-256b and the backside source/drain contact 258 formed in the trench 252 of the first alternative workpiece 200 have planar top and bottom surfaces. Other portions of the silicide layers 256a-256b and the backside source/drain contact 258 that fill the voids 224 may still have non-planar surfaces.

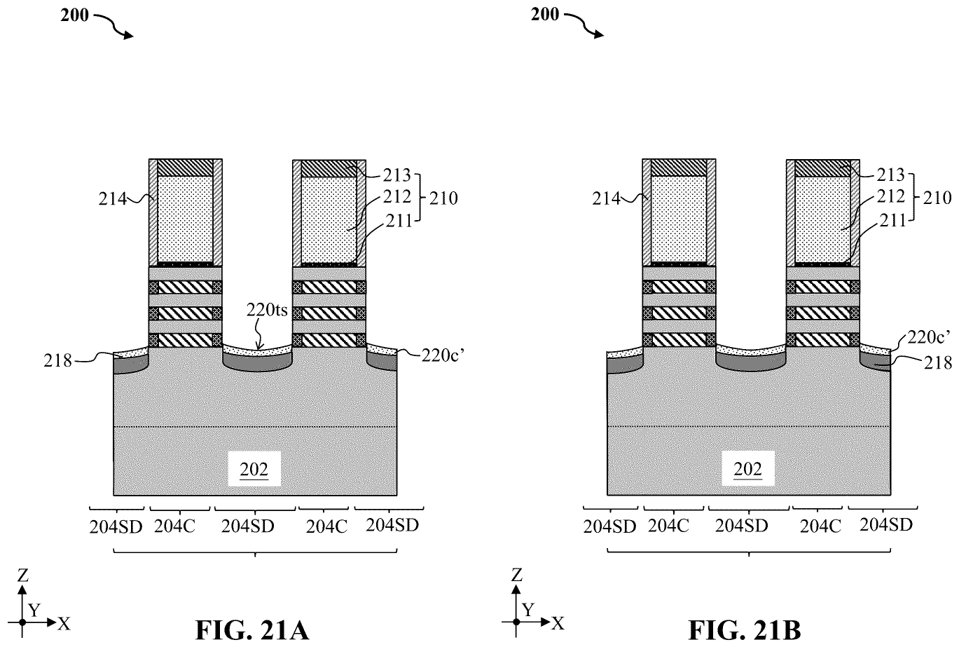

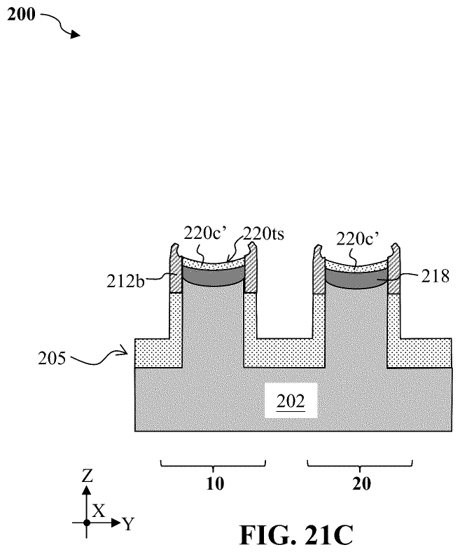

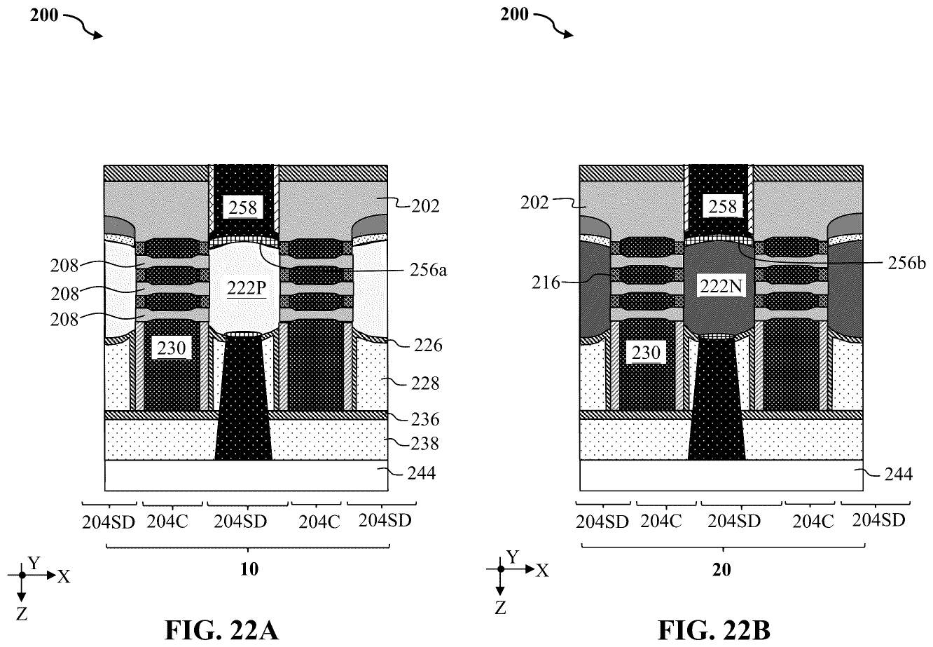

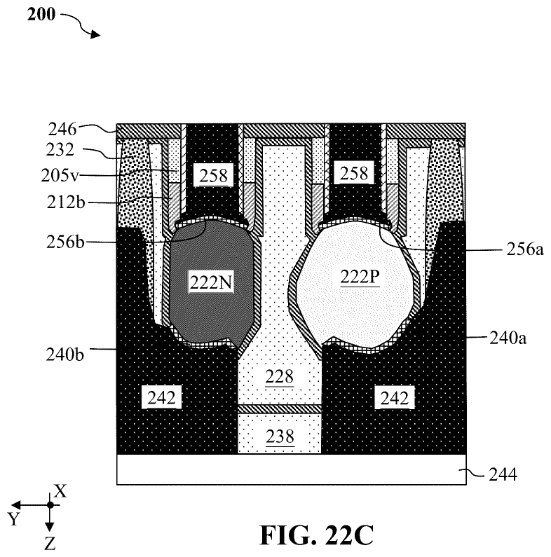

FIGS. 21A-21C and FIGS. 22A-22C depict cross-sectional views of a second alternative workpiece during various fabrication stages in the method of FIG. 1, according to one or more aspects of the present disclosure. The workpiece 200 represented by FIGS. 21A-21C is similar to the workpiece 200 represented by FIGS. 8A-8C, and differences between these two workpieces include the different profiles of the top surface of the semiconductor layer 218 and the dielectric layer 220c′ formed on the semiconductor layer 218. In this alternative embodiment, by performing a shorter duration of epitaxial growth process than that of the semiconductor layer 218 shown in FIG. 19A, the top surface 218ts of the semiconductor layer 218 is below the top surface 202ts of the substrate 202 and is a concave top surface. The dielectric layer 220c′ tracks the shape of the top surface of the semiconductor layer 218 and thus has a concave top surface. The dielectric layer 220c′ is in direct contact with both the substrate 202 and the bottommost inner spacer feature 216. Operations in blocks 114-130 may be then performed to form final structure of the workpiece according to this alternative embodiment. The resulted workpiece shown in FIGS. 22A-22C is similar to the workpiece 200 represented by FIGS. 16A-16C, and differences between these two workpieces include the different profiles of the silicide layers 256a-256b and the backside source/drain contact 258. More specifically, after being flipped over, as illustrated in FIGS. 22A-22C, the portions of the silicide layers 256a-256b formed in the trench 252 have convex top and bottom surfaces, and the backside source/drain contact 258 formed in the trench 252 has a convex bottom surface 258bs.

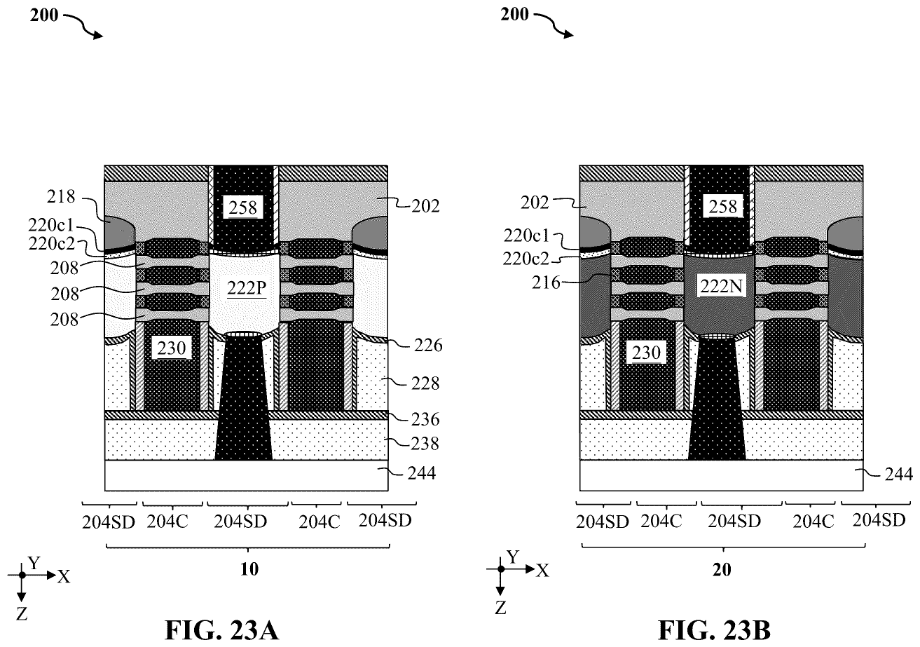

In the above embodiments, the dielectric layer 220c′ is a single-layer structure. In an alternative embodiments, the dielectric layer 220c′ may be a multi-layer structure, such as a dual-layer structure represented by FIGS. 23A-23B. The dielectric layer 220c′ shown in FIGS. 23A-23B includes a first layer 220c1 in direct contact with the semiconductor layer 218 and a second layer 220c2 in direct contact with the first layer 220c1. The first layer 220cl and the second layer 220c2 may have different composition. The first layer 220cl may include an oxide layer, such as silicon oxide. The second layer 220c2 may include a nitride layer, such as silicon nitride, silicon oxycarbonitride, silicon carbonitride. A thickness of the first layer 220cl may be in a range between about 1 nm and 2 nm, and a thickness of the second layer 220c2 may be in a range between about 3 nm and about 4 nm.

Although not intended to be limiting, one or more embodiments of the present disclosure provide many benefits to a semiconductor structure and the formation thereof. For example, a backside source/drain contact opening may be laterally enlarged to expose a larger surface of the source/drain feature without substantially reducing a volume of the source/drain feature from its back side, thereby facilitating the formation of a silicide layer that has a larger contact area with the source/drain feature.

The present disclosure provides for many different embodiments. Semiconductor structures and methods of fabrication thereof are disclosed herein. In one exemplary aspect, the present disclosure is directed to a method. The method includes receiving a workpiece comprising a fin-shaped active region protruding from a substrate and comprising a channel region and a source/drain region, and a dummy gate stack over the channel region. The method also includes recessing the source/drain region to form a source/drain trench exposing the substrate, forming a dielectric layer over the substrate and in the source/drain trench, epitaxially forming a source/drain feature in the source/drain trench and in direct contact with a top surface of the dielectric layer, replacing the dummy gate stack with a gate structure, removing the dielectric layer and a portion of the substrate disposed directly under the dielectric layer to form a first contact opening, forming a silicide layer in the first contact opening and under the source/drain feature, and forming a conductive layer under the silicide layer to fill a remaining portion of the first contact opening.

In some embodiments, the method may also include, before the forming of the dielectric layer, epitaxially forming an undoped semiconductor layer in the source/drain trench, wherein the undoped semiconductor layer is in direct contact with the substrate. In some embodiments, the forming of the dielectric layer may include depositing a dielectric material layer over the workpiece, the dielectric material layer comprising a first portion extending along a top surface of the undoped semiconductor layer and a second portion extending along a sidewall surface of the channel region, wherein the first portion is thicker than the second portion, and removing the second portion of the dielectric material layer. In some embodiments, the workpiece may also include an isolation feature disposed between the fin-shaped active region and another fin-shaped active region, and a spacer feature on the isolation feature and in direct contact with the source/drain region of the fin-shaped active region, wherein, upon completion of the epitaxially forming of the source/drain feature, the source/drain feature, the dielectric layer, and the spacer feature enclose an air gap in a first cross-sectional view cut through the isolation feature and the fin-shaped active region. In some embodiments, a portion of the silicide layer substantially fills the air gap. In some embodiments, a portion of the silicide layer and a portion of the conductive layer substantially fill the air gap. In some embodiments, the method may also include, after replacing the dummy gate stack with the gate structure, forming a second contact opening exposing a top surface of the source/drain feature, and forming a source/drain contact in the second contact opening. In some embodiments, the fin-shaped active region may include a vertical stack of alternating channel layers and sacrificial layers, and the replacing of the dummy gate stack with the gate structure may include selectively removing the dummy gate stack to form a gate trench, selectively removing the sacrificial layers to form gate openings, and forming the gate structure in the gate trench and the gate openings. In some embodiments, the removing of the dielectric layer and the portion of the substrate disposed directly under the dielectric layer to form the first contact opening may include performing a first etching process to selectively remove the portion of the substrate disposed directly under the dielectric layer to expose the dielectric layer to form a trench, and performing a second etching process to selectively remove the dielectric layer to enlarge the trench to form the first contact opening. The method may also include, after the performing of the first etching process and before the performing of the second etching process, forming a dielectric barrier layer extending along sidewall surface of the trench.

In another exemplary aspect, the present disclosure is directed to a method. The method includes forming a source/drain opening extending into a substrate, forming a semiconductor layer in a bottom portion of the source/drain opening, forming a dielectric feature in the source/drain opening and on the semiconductor layer, epitaxially growing a source/drain feature in the source/drain opening, wherein the source/drain feature is in direct contact with the dielectric feature, removing the semiconductor layer and a portion of the substrate disposed directly under the semiconductor layer to form a trench, selectively removing the dielectric feature to enlarge the trench, after the selectively removing of the dielectric feature, forming a silicide layer in the enlarged trench, and depositing a conductive layer in the enlarged trench and in direct contact with the silicide layer.

In some embodiments, a top surface of the semiconductor layer may be above a top surface of the substrate, and wherein the dielectric feature comprises a convex top surface. In some embodiments, a top surface of the semiconductor layer may be substantially coplanar with a top surface of the substrate, and the dielectric feature may include a substantially planar top surface. In some embodiments, a top surface of the semiconductor layer may be under a top surface of the substrate, and the dielectric feature may include a concave top surface. In some embodiments, the dielectric feature may include a first dielectric layer disposed on a second dielectric layer, the first and second dielectric layers may include different compositions. The method may also include, planarizing the substrate from its back side, forming a hard mask layer under the planarized substrate, forming an oxide layer under the hard mask layer, patterning the hard mask layer and the oxide layer to form an opening exposing the semiconductor layer and the portion of the substrate disposed directly under the semiconductor layer, and after the depositing of the conductive layer, performing a planarization process from back side of the conductive layer, wherein the performing of the planarization process further removes oxide layer.

In yet another exemplary aspect, the present disclosure is directed to a semiconductor structure. The semiconductor structure includes a gate structure wraps around a plurality of nanostructures disposed over a substrate, a first source/drain feature coupled to the plurality of nanostructures and adjacent to the gate structure, a first silicide layer in direct contact with a bottom surface of the first source/drain feature, a first source/drain contact disposed directly under the first source/drain feature and in direct contact with the first silicide layer, and a dielectric barrier layer providing isolation between the substrate and the first source/drain contact, wherein, in a first cross-sectional view cut through the gate structure and the first source/drain feature, a portion of the first silicide layer is vertically disposed between the dielectric barrier layer and the first source/drain contact.

In some embodiments, in a second cross-sectional view cut through the first source/drain feature without cutting through the gate structure, the first silicide layer spans a first width, and the first source/drain contact spans a second width less than the first width. In some embodiments, the semiconductor structure may also include a second silicide layer in direct contact with a top surface of the first source/drain feature, and a second source/drain contact disposed directly on the first source/drain feature and in direct contact with the second silicide layer. In some embodiments, the semiconductor structure may also include a second source/drain feature coupled to the plurality of nanostructures, wherein the plurality of nanostructures are disposed between the first and second source/drain features, a dielectric layer in direct contact with a bottom surface of the second source/drain feature, and an undoped semiconductor layer disposed between the dielectric layer and the substrate.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an active region extending lengthwise along a first direction over a substrate;
forming an isolation feature alongside the active region, wherein a top surface of the isolation feature is non-planar when viewed along the direction;
removing a portion of the active region to form a source/drain trench;
forming a dielectric layer in a lower portion of the source/drain trench;
epitaxially growing a semiconductor feature over the dielectric layer and in an upper portion of the source/drain trench, wherein when viewed along the direction, an air gap is enclosed by the dielectric layer and the semiconductor feature;
forming an opening extending through the substrate from its back to expose a bottom surface of the dielectric layer;
selectively removing the dielectric layer, wherein the selectively removing of the dielectric layer breaks an enclosure of the air gap; and
forming a conductive feature in the opening and filling the air gap.

2. The method of claim 1, further comprising:
forming a dummy gate stack over the active region;
forming gate spacers extending along sidewalls of the dummy gate stack; and
after the forming of the semiconductor feature, replacing the dummy gate stack with a gate structure.

3. The method of claim 2, further comprising:
forming fin sidewall spacers along with the forming of the gate spacers, wherein the fin sidewall spacers are disposed on the isolation feature and adjacent to a lower portion of the active region.

4. The method of claim 3, wherein the air gap exposes a sidewall surface of one of the fin sidewall spacers.

5. The method of claim 1, wherein the forming of the conductive feature comprises:
forming a silicide layer; and
after the forming of the silicide layer, forming a conductive layer.

6. The method of claim 5, wherein a portion of the silicide layer and a portion of the conductive layer substantially fill the air gap.

7. The method of claim 1, further comprising:
after the forming of the opening and before the selectively removing of the dielectric layer, forming a dielectric liner extending along sidewalls of the opening,
wherein a portion of the conductive feature is vertically overlapped with the dielectric liner.

8. The method of claim 1, wherein the active region further comprises a channel region comprising a plurality of nanostructures.

9. The method of claim 1, further comprising:
before the forming of the dielectric layer, epitaxially growing a semiconductor layer in the source/drain trench, wherein the semiconductor layer is undoped.

10. The method of claim 9, wherein the semiconductor layer has a convex top surface when viewed along the direction.

11. A method, comprising:
forming a stack of alternating channel layers and sacrificial layers over a substrate;
patterning the stack and a top portion of the substrate to form a fin-shaped structure;
forming a first isolation structure alongside the patterned top portion of the substrate;
removing a portion of the fin-shaped structure to form a trench,
forming a source/drain feature in the trench, wherein a portion of the source/drain feature overhangs the first isolation structure;
forming a second isolation structure extend lengthwise along a direction parallel to that of the fin-shaped structure, the second isolation structure extending into the first isolation structure; and
forming a metal contact disposed over and electrically coupled to the source/drain feature,
wherein a portion of the metal contact extends into the second isolation structure.

12. The method of claim 11, further comprising:
before the forming of the source/drain feature, forming a dielectric layer in the trench, wherein upon formation of the source/drain feature, an air gap is enclosed by the source/drain feature and the dielectric layer.

13. The method of claim 12, wherein the air gap is visible in a first cross-sectional view cut through the source/drain feature and the first isolation structure, and is invisible in a second cross-sectional view different from the first cross-sectional view.

14. The method of claim 12, further comprising:
removing a part of the patterned top portion of the substrate, thereby forming a backside opening under the dielectric layer;
selectively removing the dielectric layer without substantially etching the source/drain feature; and
forming a backside via in the backside opening.

15. The method of claim 14, wherein a width of a portion of the backside via adjacent to the source/drain feature is greater than a width of a portion of the backside via away from the source/drain feature.

16. The method of claim 14, further comprising:
selectively removing the sacrificial layers; and
forming a gate structure wrapping around the channel layers.

17. A method, comprising:
forming an undoped semiconductor layer in a source/drain opening, the source/drain opening exposing a top surface of a substrate;
forming a dielectric layer on the undoped semiconductor layer;
epitaxially growing a source/drain feature over the dielectric layer, wherein the source/drain feature comprises a first semiconductor layer and a second semiconductor layer, and a portion of a surface of the source/drain feature and a portion of a surface of the dielectric layer are exposed to an air gap;
depositing a contact etch stop layer (CESL) extending along a top surface of the source/drain feature;
depositing an interlayer dielectric (ILD) layer over the CESL;
planarizing the substrate from its back;
forming a trench extending through the substrate to expose the dielectric layer;
selectively removing the dielectric layer, wherein the selectively removing exposes the air gap; and
forming a conductive feature in the trench.

18. The method of claim 17, further comprising:
forming a dielectric liner disposed between the substrate and the conductive feature.

19. The method of claim 17, wherein the conductive feature is further formed in the air gap.

20. The method of claim 17, further comprising:
before the forming of the conductive feature, forming a silicide layer, wherein a width of the silicide layer is greater than a width of the trench.
